(19) United States
(12) Patent Application Publication
(10) Pub. No.: US 2024/0178632 A1
(43) Pub. Date: May 30, 2024

(54) SEMICONDUCTOR LASER DEVICE, SUBMOUNT, SUBMOUNT ASSEMBLY, AND METHOD OF TESTING SEMICONDUCTOR LASER DEVICE

(71) Applicant: Nuvoton Technology Corporation Japan, Kyoto (JP)

(72) Inventors: Yasuo BABA, Toyama (JP); Tohru NISHIKAWA, Toyama (JP)

(21) Appl. No.: 18/435,836

(22) Filed: Feb. 7, 2024

Related U.S. Application Data
(63) Continuation-in-part of application No. PCT/JP2022/010213, filed on Mar. 9, 2022.
(60) Provisional application No. 63/231,417, filed on Aug. 10, 2021.

(51) Int. Cl. H01S 5/023; H01S 5/02212

(52) U.S. Cl. CPC H01S 5/023; H01S 5/02212

(57) ABSTRACT

A semiconductor laser device includes: a pedestal; a submount that is joined to the pedestal via solder; and a semiconductor laser that is mounted on the submount. When a view of the submount from a side on which the semiconductor laser is mounted is defined as a top view, in the top view: the solder includes a plurality of protruding portions; and the plurality of protruding portions are provided on the pedestal outside the submount, protrude in directions away from an inside of the submount, and are located at regular intervals on at least a portion of a periphery of the submount.

### CROSS REFERENCE TO RELATED APPLICATIONS

This is a continuation-in-part application of PCT International Application No. PCT/JP2022/010213 filed on Mar. 9, 2022, designating the United States of America, which is based on and claims priority of U.S. Provisional Patent Application No. 63/231,417 filed on Aug. 10, 2021. The entire disclosures of the above-identified applications, including the specifications, drawings and claims are incorporated herein by reference in their entirety.

### FIELD

The present disclosure relates to a semiconductor laser device, a solder-provided submount used when a semiconductor laser device is manufactured, a solder-provided submount assembly for manufacturing solder-provided submounts, and a method of testing a semiconductor laser device.

### BACKGROUND

Conventionally, a light source module including a TO-CAN package has been known as a semiconductor laser device including a semiconductor laser. The TO-CAN package includes: a base that is disc-shaped; a post that stands on the base; a pair of lead pins that penetrate the base; and a metal cap that is fixed to the base to cover the post.

In the semiconductor laser device including the TO-CAN package, the semiconductor laser is mounted on the post that is a pedestal with a submount interposed therebetween. In the semiconductor laser device thus configured, the semiconductor laser emits laser light with electric power supplied from the lead pins. The laser light emitted from the semiconductor laser exits through a light-transmitting window provided on the top surface of the cap to the outside.

### CITATION LIST

### Patent Literature

PTL 1: International Publication No. WO 2020/031944

### SUMMARY

### Technical Problem

When a semiconductor laser is mounted on a pedestal with a submount interposed therebetween, it is conceivable to use a solder-provided submount obtained by providing a solder layer on the submount in advance. In this case, by heating the solder-provided submount to melt the solder layer, the submount and the pedestal are joined with solder.

However, when the submount is joined to the pedestal using the solder-provided submount, the molten solder of the solder layer may protrude from the outer edge of the submount. When, for example, the solder protrudes from the submount extremely lopsidedly, the submount usually tilts relative to the pedestal. As a result, the semiconductor laser mounted on the submount also tilts, and the optical precision of the semiconductor laser device deteriorates.

The present disclosure has been conceived to solve such a problem, and has an object to provide, for example, a semiconductor laser device that is capable of preventing a submount from tilting relative to a pedestal.

### Solution to Problem

In order to achieve the object, a semiconductor laser device according to one aspect of the present disclosure includes: a pedestal; a submount that is joined to the pedestal via solder; and a semiconductor laser that is mounted on the submount, wherein when a view of the submount from a side on which the semiconductor laser is mounted is defined as a top view, in the top view: the solder includes a plurality of protruding portions; and the plurality of protruding portions are provided on the pedestal outside the submount, protrude in directions away from an inside of the submount, and are located at regular intervals on at least a portion of a periphery of the submount.

A submount according to one aspect of the present disclosure is a submount that is to be disposed on a pedestal and includes: an insulative component; a metal film; and a solder layer, wherein when a direction that corresponds to a side closer to the pedestal when the submount is disposed on the pedestal is defined as a lower side, and a direction that corresponds to a side opposite to the side closer to the pedestal is defined as an upper side, the metal film is disposed on a lower surface of the insulative component, the solder layer is disposed on a lower surface of the metal film, and an outer edge of the lower surface of the metal film includes a portion in which a first region in which the solder layer is located and a second region in which the solder layer is not located are alternately located.

A submount assembly according to one aspect of the present disclosure is a submount assembly that is an assembly of submounts each of which is to be disposed on a pedestal and includes: a substrate; a metal film; and a solder layer, wherein when a side closer to the pedestal is defined as a lower side, and a side opposite to the side closer to the pedestal is defined as an upper side, the metal film is disposed on a lower surface of the substrate, the solder layer is disposed on a lower surface of the metal film, grooves in a lattice pattern are provided on an upper surface of the submount assembly or alteration portions in a lattice pattern are provided inside the substrate, and a portion in which regions not including the solder layer are located at regular intervals is located immediately below one of the grooves or one of the alteration portions.

A testing method according to one aspect of the present disclosure is a method of testing a semiconductor laser device, wherein the semiconductor laser device includes: a pedestal; a pedestal; a semiconductor laser that is mounted on the submount, when a view of the submount from a side on which the semiconductor laser is mounted is defined as a top view, in the top view: the solder includes a protruding region that protrudes from an outer edge of the submount, the solder includes a protruding region that protrudes from an outer edge of the submount, the method includes determining a tilt of the submount by measuring a state of the plurality of protruding portions.

### Advantageous Effects

The semiconductor laser device according to the present disclosure is capable of preventing the submount from tilting relative to the pedestal. Moreover, the solder-provided submount according to the present disclosure is capable of preventing the submount from tilting when the submount is joined to the pedestal. Furthermore, the solder-provided submount assembly according to the present disclosure makes it possible to obtain the solder-provided submount that is prevented from titling when joined to the pedestal. In addition, the method of testing the semiconductor laser device according to the present disclosure makes it possible to determine the tilt of the submount joined to the pedestal.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a cross-sectional view of a semiconductor laser device according to an embodiment.

FIG. 2 is a cross-sectional view of the semiconductor laser device according to the embodiment.

FIG. 3 is a diagram illustrating a configuration of a pedestal and solder when a submount and a semiconductor laser are removed in the semiconductor laser device according to the embodiment.

FIG. 4 is a view of a configuration of the solder, the submount, and the semiconductor laser in the semiconductor laser device according to the embodiment.

FIG. 5 is an enlarged view of the configuration of the solder in the semiconductor laser device according to the embodiment.

FIG. 6 is a diagram illustrating a state in which solder protrudes from the submount in the semiconductor laser device according to the embodiment.

FIG. 7 is a diagram illustrating a state in which solder protrudes from the submount in the semiconductor laser device according to Variation 1.

FIG. 8 is a diagram illustrating a state in which solder protrudes from the submount in the semiconductor laser device according to Variation 2.

FIG. 9 is a diagram illustrating a state in which solder protrudes from the submount in the semiconductor laser device according to Variation 3.

FIG. 10 is a diagram illustrating a state in which solder protrudes from the submount in the semiconductor laser device according to Variation 4.

FIG. 11 is a diagram illustrating a state in which solder protrudes from the submount in the semiconductor laser device according to Variation 5.

FIG. 12 is a diagram illustrating a state in which solder protrudes from the submount in the semiconductor laser device according to Variation 6.

FIG. 13 is a cross-sectional view of a semiconductor laser device according to Variation 7.

FIG. 14 is a view of a configuration of a solder-provided submount according to the embodiment.

FIG. 15 is a cross-sectional view of the solder-provided submount according to the embodiment.

FIG. 16 is a flow chart illustrating a method of manufacturing a semiconductor laser device according to the embodiment.

FIG. 17 is a rear view of a solder-provided submount according to Variation 1.

FIG. 18 is a rear view of a solder-provided submount according to Variation 2.

FIG. 19 is a rear view of a solder-provided submount according to Variation 3.

FIG. 20 is a rear view of a solder-provided submount according to Variation 4.

FIG. 21 is a rear view of a solder-provided submount according to Variation 5.

FIG. 22 is a view of a configuration of a solder-provided submount assembly according to the embodiment.

FIG. 23 is a flow chart illustrating a method of manufacturing a solder-provided submount according to the embodiment.

FIG. 24 is a view of a configuration of a solder-provided submount obtained by the method of manufacturing the solder-provided submount according to the embodiment.

FIG. 25 is a view of a configuration of a solder-provided submount assembly according to Variation 1.

FIG. 26 is a view of configurations of solder-provided submounts obtained from the solder-provided submount assembly according to Variation 1.

FIG. 27 is a flow chart illustrating a variation of the method of manufacturing the solder-provided submount.

FIG. 28 is a view of a configuration of a solder-provided submount assembly according to Variation 2.

FIG. 29 is a view of configurations of solder-provided submounts obtained from the solder-provided submount assembly according to Variation 2.

FIG. 30 is a view of a configuration of a solder-provided submount assembly according to Variation 3.

FIG. 31 is a view of a configuration of a solder-provided submount assembly according to Variation 4.

### DESCRIPTION OF EMBODIMENT

Hereinafter, embodiments of the present disclosure are described with reference to the drawings. It should be noted that each of the embodiments described below shows a specific example of the present disclosure. Accordingly, the numerical values, shapes, materials, constituent elements, the arrangement and connection of the constituent elements, and steps (processes) and the sequence of the steps, etc. shown in the following embodiments are mere examples, and are not intended to limit the scope of the present disclosure. Therefore, among the constituent elements in the following embodiments, those not recited in any one of the independent claims that indicate the broadest concepts of the present disclosure are described as optional constituent elements.

Moreover, the respective figures are schematic diagrams and are not necessarily precise illustrations. Accordingly, the scales etc. in the respective figures are not necessarily uniform. In the drawings, the same reference signs are assigned to substantially identical components, and overlapping description is omitted or simplified.

### Embodiment

### [Semiconductor Laser Device]

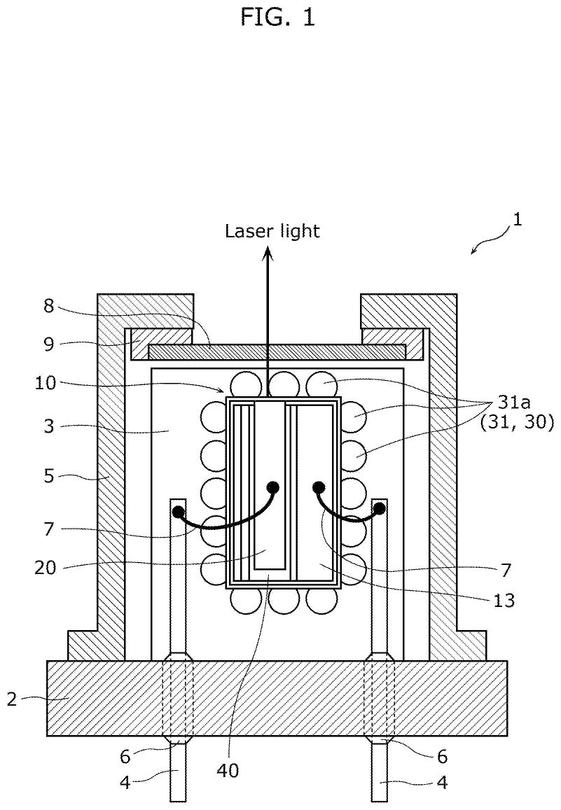

First, a configuration of semiconductor laser device 1 according to an embodiment is described with reference to FIG. 1 to FIG. 4.

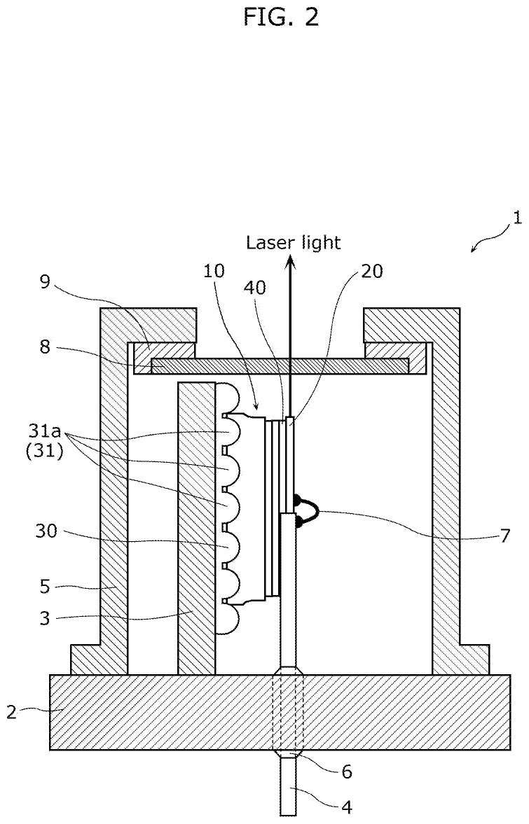

FIG. 1 and FIG. 2 are each a cross-sectional view of semiconductor laser device 1 according to the embodiment. FIG. 1 shows a cross section in a top view of submount 10 and semiconductor laser 20, and FIG. 2 shows a cross section in a side view of submount 10 and semiconductor laser 20.

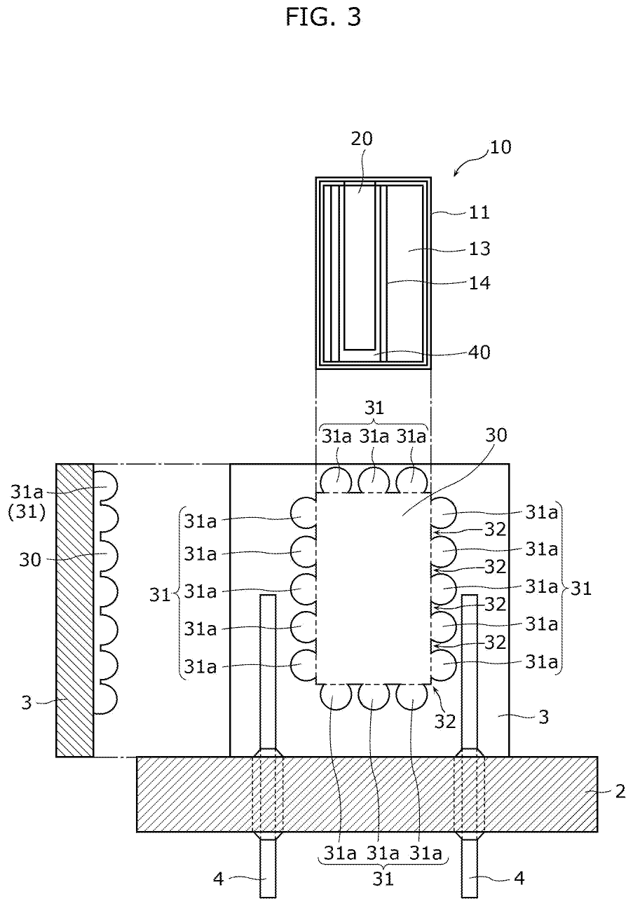

FIG. 3 is a diagram illustrating a configuration of pedestal 3 and solder 30 when submount 10 and semiconductor laser 20 are removed in semiconductor laser device 1 according to the embodiment. It should be noted that FIG. 3 shows a partial configuration of semiconductor laser device 1. It should be also noted that the shape of solder 30 shown in FIG. 3 indicates a shape after submount 10 is joined to pedestal 3 (i.e., a shape after melting and pressing by reflow).

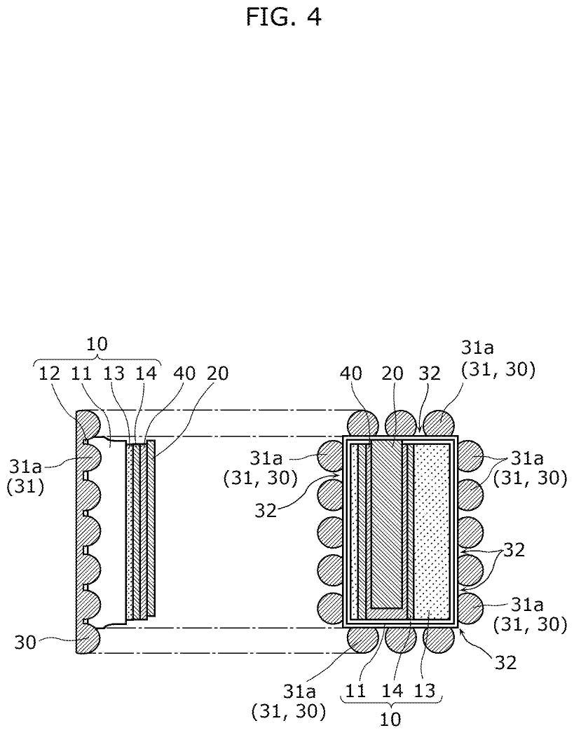

FIG. 4 is a view of a configuration of solder 30, submount 10, and semiconductor laser 20 in semiconductor laser device 1 according to the embodiment. In FIG. 4, (a) is a side view and (b) is a top view. It should be noted that for the sake of clarity of a connection relation of each component in side view (a) and top view (b), hatching is provided in FIG. 4.

As shown in FIG. 1 and FIG. 2, semiconductor laser device 1 according to the present embodiment is a light-emitting module in which semiconductor laser 20 is packaged. Specifically, semiconductor laser device 1 is a light source module of a TO-CAN package type.

Semiconductor laser device 1 includes, as a TO-CAN package: base 2 that is disc-shaped; pedestal (post) 3 that stands on base 2; a pair of lead pins 4 that penetrate base 2; and cap 5 that is made of metal and disposed on base 2 to cover pedestal 3.

Base 2 and pedestal 3 constitute a stem with electrode terminals. Base 2 is a stem base, and pedestal 3 is a stem post. Base 2 and pedestal 3 contain a metal material. Although base 2 and pedestal 3 contain copper (Cu) in the present embodiment, the present disclosure is not limited to this example.

The pair of lead pins 4 are feeder terminals for supplying an electric current to semiconductor laser 20. The pair of lead pins 4 are fixed to base 2 by being inserted into through holes provided in base 2. The pair of lead pins 4 fixed to base 2 are insulated from base 2 with insulating component 6. The pair of lead pins 4 supply an electric current to a pair of electrodes of semiconductor laser 20. One of the pair of lead pins 4 is connected to one of the pair of electrodes of semiconductor laser 20 with gold wire 7. Moreover, a remaining one of the pair of lead pins 4 is connected to second metal film 13 (an upper metal layer) of submount 10 with gold wire 7. Second metal film 13 of submount 10 is electrically connected to a remaining one of the pair of electrodes of semiconductor laser 20. It should be noted that semiconductor laser 20 includes a p-side electrode and an n-side electrode as the pair of electrodes.

Cap 5 is a cover that covers pedestal 3, submount 10 attached to pedestal 3, and semiconductor laser 20. In other words, submount 10 and semiconductor laser 20 are housed in an enclosed space provided by base 2 and cap 5. Cap 5 is fixed to base 2 to cover pedestal 3, submount 10, and semiconductor laser 20. Base 2 and cap 5 are joined by, for example, welding.

A light-transmitting window (light-extracting window) is provided on the top surface of cap 5 to allow light emitted from semiconductor laser 20 to pass. Specifically, an opening is provided on the top surface of cap 5, and plate glass 8 that is transparent is disposed to cover the opening. Plate glass 8 is disposed opposite to a light-emitting surface of semiconductor laser 20. Plate glass 8 is joined to cap 5 with adhesive 9 such as low melting glass.

Semiconductor laser device 1 includes submount 10 and semiconductor laser 20, and is packaged using the TO-CAN package.

Submount 10 is mounted above pedestal 3. Specifically, submount 10 is mounted on pedestal 3.

Submount 10 is joined to pedestal 3 via solder 30. To put it another way, submount 10 and pedestal 3 are joined with solder 30. Accordingly, solder 30 is located between submount 10 and pedestal 3. Solder 30 is an example of a joint material. In the present embodiment, AuSn solder (gold-tin solder) is used as solder 30. Submount 10 serves as a supporting component that supports semiconductor laser 20, and at the same serves as a heat dissipating component that dissipates heat of semiconductor laser 20. For this reason, submount 10 may contain a material having a superior heat conductivity.

As shown in FIG. 3 and FIG. 4, submount 10 includes insulative component 11, first metal film 12 that is located on a lower side of insulative component 11 (a side closer to pedestal 3), and second metal film 13 and barrier film 14 that are located on an upper side of insulative component 11.

Insulative component 11 is a submount body that contains an insulative material. Insulative component 11 may contain a highly heat-conductive material such as diamond, SiC, or AlN. SiC or AlN may be formed of a single crystal or a ceramic. In the present embodiment, insulative component 11 contains diamond. Moreover, the shape of insulative component 11 is substantially a cuboid. Specifically, insulative component 11 is in a rectangular plate shape. In other words, the top view shape of insulative component 11 is a rectangle.

In the present embodiment, the outer edge (outer peripheral edge) of submount 10 is the outer edge (outer peripheral edge) of insulative component 11. Accordingly, the top view shape of submount 10 is a rectangle. Specifically, the top view shape of each of submount 10 and insulative component 11 is an oblong.

First metal film 12 is disposed on almost the entire bottom surface of insulative component 11 (a surface on the side closer to pedestal 3). In other words, first metal film 12 is a lower metal film located on the lower side of insulative component 11, and is provided on the side closer to pedestal 3 (i.e., the side opposite to a side closer to semiconductor laser 20). As an example, first metal film 12 has a three-layer structure (Ti/Pt/Au) including a titanium layer (Ti layer) provided on the bottom surface of insulative component 11, a platinum layer (Pt layer) provided on the bottom surface of the titanium layer, and a gold layer (Au layer) provided on the bottom surface of the platinum layer, and the surface of first metal film 12 has a high solder wettability. It should be noted that the plan view shape of first metal film 12 is a rectangle.

Second metal film 13 is disposed on almost the entire top surface of insulative component 11 (a surface on the side closer to semiconductor laser 20). In other words, second metal film 13 is an upper metal layer located on the upper side of insulative component 11, and is provided on the side closer to semiconductor laser 20 (i.e., the side opposite to the side closer to pedestal 3). As an example, second metal film 13 has a three-layer structure (Ti/Pt/Au) including a titanium layer (Ti layer) provided on the top surface of insulative component 11, a platinum layer (Pt layer) provided on the top surface of the titanium layer, and a gold layer (Au layer) provided on the top surface of the platinum layer. It should be noted that the plan view shape of second metal film 13 is a rectangle.

Barrier film 14 is provided on the top surface of second metal film 13 (a surface on the side closer to semiconductor laser 20). Barrier film 14 is a barrier film that prevents diffusion of the chemical elements of solder 40 when semiconductor laser 20 and submount 10 are joined. As an example, barrier film 14 is a platinum layer (Pt layer). It should be noted that the plan view shape of barrier film 14 is a rectangle. Additionally, barrier film 14 has a width less than the width of second metal film 13.

Semiconductor laser 20 is mounted above submount 10. Specifically, semiconductor laser 20 is mounted on submount 10. Since submount 10 is located on pedestal 3, submount 10 is located between semiconductor laser 20 and pedestal 3.

It should be noted that although a mounting mode of semiconductor laser 20 may be either junction down mounting or junction up mounting, semiconductor laser 20 is mounted on submount 10 by the junction down mounting in the present embodiment.

Semiconductor laser 20 and submount 10 are joined via solder 40. In other words, semiconductor laser 20 and submount 10 are joined with solder 40. Accordingly, solder 40 is located between semiconductor laser 20 and submount 10. In the present embodiment, solder 40 is located between semiconductor laser 20 and barrier film 14 of submount 10, and joins semiconductor laser 20 and barrier film 14 together. Solder 40 is an example of a joint material. In the present embodiment, AuSn solder is used as solder 40.

It should be noted that solder 30 is located between pedestal 3 and first metal film 12 of submount 10, and joins pedestal 3 and first metal film 12 together.

Moreover, semiconductor laser 20 is disposed closer to one side in a shorter-side direction (width direction) of submount 10. In other words, semiconductor laser 20 is disposed at a position offset to the center of submount 10 in the width direction. Specifically, in FIG. 3 and FIG. 4, the position of semiconductor laser 20 is closer to the left side from the center of submount 10 in the width direction.

Semiconductor laser 20 is a semiconductor laser chip that emits laser light. Semiconductor laser 20 emits laser light with an electric current supplied from the pair of lead pins 4. The laser light emitted from semiconductor laser 20 exits through plate glass 8 (a light-transmitting window) provided on the top surface of cap 5 to the outside. Semiconductor laser 20 emits laser light having a predetermined wavelength. Specifically, semiconductor laser 20 emits ultraviolet laser light, visible laser light, or infrared laser light. Although semiconductor laser 20 is, for example, a GaN-based semiconductor laser that contains a nitride semiconductor material, a semiconductor material contained in semiconductor laser 20 is not limited to this example.

When semiconductor laser 20 and submount 10 are mounted on pedestal 3, semiconductor laser 20 and submount 10 are joined by means of solder 40, and at the same time submount 10 and pedestal 3 are joined by means of solder 30. At this time, since submount 10 and pedestal 3 are joined with molten solder and submount 10 is pressed toward pedestal 3, the pressing force causes solder 30 in a molten state (i.e., solder 30 prior to melting) located between submount 10 and pedestal 3 to protrude from submount 10 as shown in FIG. 1 to FIG. 4. Specifically, solder 30 in the molten state expands from the outer edge of submount 10 toward the outside, and at the same time extends in a thickness direction of submount 10.

As shown in FIG. 3 and FIG. 4, when a view of submount 10 from a side on which semiconductor laser 20 is mounted is defined as a “top view,” in the top view, solder 30 includes protruding region 31 that is a region in which solder 30 protrudes from the outer edge of submount 10 (in a direction opposite to the inside of submount 10). In the present embodiment, since the outer edge of insulative component 11 is the outer edge of submount 10, protruding region 31 is a portion of solder 30 that protrudes from insulative component 11.

In the top view, protruding region 31 of solder 30 includes a plurality of protruding portions 31a each of which protrudes toward the outside. In the present embodiment, each of the plurality of protruding portions 31a is a protruding portion that protrudes from the outer edge of submount 10. Moreover, the plurality of protruding portions 31a are intermittently located around the periphery of submount 10. Each of the plurality of protruding portions 31a is in a shape forming a portion of a substantially spherical shape. Accordingly, in the top view, each of the plurality of protruding portions 31a is in a shape forming a portion of a substantially circular shape. Specifically, in the top view, each of the plurality of protruding portions 31a is a bulging portion that bulges from the outer edge of submount 10, and is in a shape including at least a semicircular portion out of a circular shape. It should be noted that each of the plurality of protruding portions 31a may be substantially half-spherical (i.e., substantially semicircular in the top view) or may be in a shape smaller than a half-sphere (i.e., a shape smaller than a semicircle in the top view).

As an example, the spheres of which the plurality of protruding portions 31a are formed have an average diameter of 60 μm, and an average height of the heights of the plurality of protruding portions 31a (the height of submount 10 in the thickness direction) is 30 μm. Moreover, as an example, solder 30 between submount 10 and pedestal 3 has a thickness of 2.5 μm (a distance between submount 10 and pedestal 3).

As another example, the spheres of which the plurality of protruding portions 31a are formed have an average diameter of 120 μm, and an average height of the heights of the plurality of protruding portions 31a (the height of submount 10 in the thickness direction) is 60 μm. Moreover, as an example, solder 30 between submount 10 and pedestal 3 has a thickness of 3.5 μm (a distance between submount 10 and pedestal 3).

In submount 10 whose top view shape is a rectangle, the plurality of protruding portions 31a of protruding region 31 may be located on all the four sides or may be located on one side, two sides, or three sides among the four sides. In the present embodiment, the plurality of protruding portions 31a are located on all the four sides.

All the plurality of protruding portions 31a in protruding region 31 comprise a plurality of protruding portions 31a that are located at regular intervals. In other words, portions of solder 30 that protrude from the outer edge of submount 10 are located at regular intervals. For example, in submount 10 whose top view shape is the rectangle, the plurality of protruding portions 31a located at regular intervals may be located on all the four sides or may be located on one side, two sides, or three sides among the four sides.

Moreover, the plurality of protruding portions 31a located at regular intervals may be all protruding portions 31a on the one side or may be some of all protruding portions 31a on the one side. As stated above, the plurality of protruding portions 31a located at regular intervals may be located in at least a portion of the periphery of submount 10.

It should be noted that a case in which a plurality of protruding portions 31a are located at regular intervals includes, for example, not only a case in which a plurality of protruding portions 31a are located at a certain distance from one another, but also a case in which a plurality of protruding portions 31a are located at a regular distance (e.g., a distance according to a certain principle) from one another.

As stated above, since the plurality of protruding portions 31a in protruding region 31 of solder 30 are located at regular intervals, solder 30 protrudes from submount 10 without solder 30 being non-uniform, and it is possible to prevent submount 10 from tilting relative to pedestal 3. For example, pedestal 3 and submount 10 are joined parallel to each other by means of solder 30. Accordingly, it is possible to improve the optical precision of laser light emitted from semiconductor laser 20 mounted on submount 10.

In particular, by providing the plurality of protruding portions 31a located at regular intervals in the same size and uniformly, it is possible to effectively prevent submount 10 from tilting. Moreover, when the top view shape of submount 10 is an oblong, submount 10 tilts easily in the shorter-side direction. For this reason, the plurality of protruding portions 31a may be symmetrically provided in the shorter-side direction of submount 10. This makes it possible to more effectively prevent submount 10 from tilting.

Furthermore, in the present embodiment, solder 30 does not protrude from the periphery of the outer edge (entire outer peripheral edge) of submount 10, and protrudes from the outer edge of submount 10 intermittently. Accordingly, a plurality of non-protruding regions 32 each of which is a region in which solder 30 does not protrude from the outer edge of submount 10 are located in a peripheral region outside of submount 10. Non-protruding region 32 is a region between two adjacent protruding portions 31a. In the top view, each of the plurality of non-protruding regions 32 is a recessed region recessed inwardly of submount 10.

As stated above, in the present embodiment, since a plurality of recessed portions are located as non-protruding regions 32 in the peripheral region outside of submount 10, the plurality of protruding portions 31a located at regular intervals define borders between the plurality of protruding portions 31a and submount 10 that are located at regular intervals.

Moreover, even when the plurality of protruding portions 31a are not located around the periphery of the outer edge of submount 10, it is possible to prevent submount 10 from tilting. Specifically, according to experiments by the inventors of the present application, it has been confirmed that, in submount 10 whose top view shape is an oblong, even when protruding regions 31 (protruding portions 31a) are not located on the shorter sides of submount 10, and protruding regions 31 (protruding portions 31a) are located only on the longer sides of submount 10, it is possible to prevent submount 10 from tilting.

It should be noted that, in the present embodiment, protruding regions 31 (protruding portions 31a) are located on all the sides of submount 10, and submount 10 has no sides on which protruding regions 31 are not located. In other words, there are no sides whose amount of protrusion is zero. This makes it possible to surely prevent submount 10 from tilting.

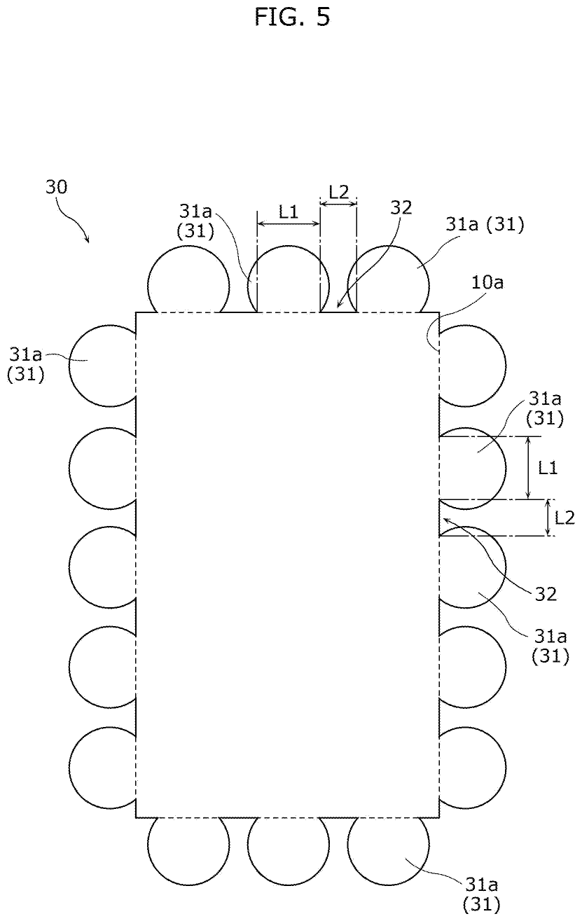

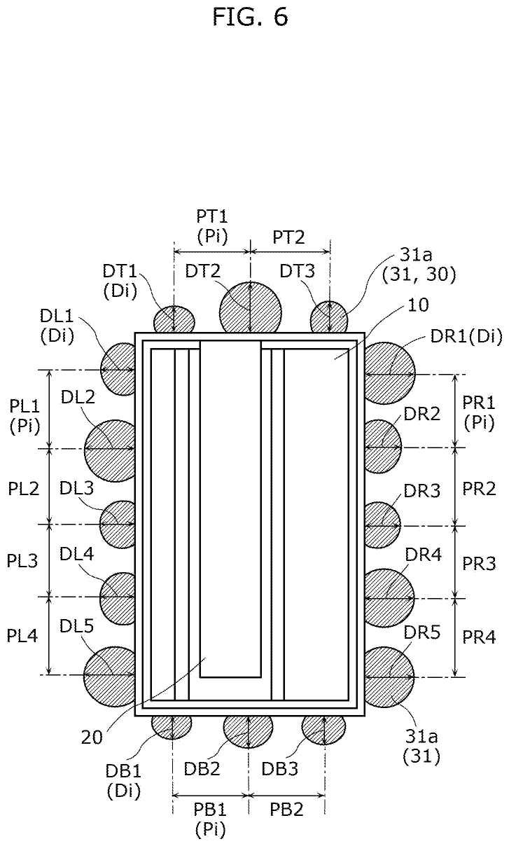

Here, desirable forms of the plurality of protruding portions 31a in protruding region 31 of solder 30 are described with reference to FIG. 5 and FIG. 6. FIG. 5 is an enlarged view of the configuration of solder 30 in semiconductor laser device 1 according to the embodiment. FIG. 6 is a diagram illustrating a state in which solder 30 protrudes from submount 10. It should be noted that dashed lines indicate the outer edge of submount 10 in FIG. 5. In other words, a region surrounded by the dashed lines in FIG. 5 is submount region 10a in which submount 10 is located.

As shown in FIG. 5, in a top view of solder 30, when the length of a border between submount 10 and one of the plurality of protruding portions 31a is denoted by L1, length L1 may be at least 20 μm and at most 200 μm. To put it another way, length L1 is the length of each protruding portion 31a on the outer edge of submount 10, and is the width of the base of each protruding portion 31a.

As stated above, setting length L1 to at least 20 μm and at most 200 μm makes it possible to prevent submount 10 from tilting and, at the same time, to effectively dissipate heat generated in semiconductor laser 20 via submount 10 and solder 30. The following describes this point.

Although the details are given below, in the present embodiment, submount 10 is joined to pedestal 3 using a solder-provided submount in which a solder layer to be solder 30 is provided in advance. In this case, the solder layer is melted with heat, and pressure is applied to submount 10. This pressure applied to submount 10 causes the molten solder layer between pedestal 3 and submount 10 to protrude from the outer edge (submount region 10a) of submount 10. Accordingly, solder 30 including protruding regions 31 (protruding portions 31a) is provided between submount 10 and pedestal 3.

At this time, the protrusion of the solder starts from one point of the solder layer prior to melting and pressure in the outer edge of submount 10. Although length L1 of a border between submount 10 and protruding region 31 (protruding portion 31a) increases as the protrusion of the solder progresses, the surface tension of the molten solder prevents the solder from protruding, toward the outside of submount 10, from a region other than a region in which the solder layer prior to melting is located in the outer edge of submount 10. For this reason, large length L1 is synonymous with a large amount of protrusion of solder in the portion (the amount of protrusion of protruding portion 31a), and the amount of solder increases locally and excessively in the outer edge of submount 10 (i.e., the solder is not sufficiently controlled). As a result, the degree of tilt of submount 10 increases. In view of the above, length L1 may be set to at most 200 μm to prevent the amount of such solder from increasing locally and excessively.

On the other hand, small length L1 means that the amount of solder is locally small in the outer edge of submount 10. As a result, a gap is more likely to exist between submount 10 mounted and pedestal 3, and heat dissipation for heat generated in semiconductor laser 20 deteriorates. In view of the above, length L1 may be set to at least 20 μm to prevent a gap from forming between submount 10 and pedestal 3.

As an example, length L1 in a shorter side of submount 10 is 80 μm, and length L1 in a longer side of submount 10 is 80 μm.

Moreover, as shown in FIG. 5, in the top view of solder 30, when the length of a portion that does not protrude from the outer edge of submount 10 and in which the outer edge of solder 30 coincides with the outer edge of submount 10 is denoted by L2, length L2 may be at most 200 μm. Length L2 is a length along the outer edge of solder 30 in non-protruding region 32 that is a region between two adjacent protruding portions 31a. In other words, length L2 is the length of a portion (a protrusion non-originating region) unadjacent to protruding region 31 (protruding portion 31a) in the outer edge of submount 10.

As stated above, since setting length L2 to at most 200 μm prevents the plurality of protruding portions 31a in protruding region 31 from becoming too discrete, it is possible to effectively prevent submount 10 from tilting. It should be noted that although the lower limit of length L2 is not particularly limited, length L2 may be at least 20 μm.

In the present embodiment, length L2 is smaller than length L1. As an example, length L2 in a shorter side of submount 10 is 50 μm, and length L1 in a longer side of submount 10 is 60 μm.

Furthermore, in FIG. 5, the plurality of protruding portions 31a in protruding region 31 have the same size (volume) in the periphery of surmount 10, and the amounts of protrusion (amounts of projection) of the plurality of protruding portions 31a are uniform, but the present disclosure is not limited to this example. Specifically, as shown in FIG. 6, the plurality of protruding portions 31a may comprise protruding portions 31a having different sizes (volumes), and the amounts of protrusion of the plurality of protruding portions 31a need not be uniform.

In this case, in submount 10 whose top view shape is a rectangle, when a total number of a plurality of protruding portions 31a on one side of the rectangle is denoted by n, and the amount of protrusion from the outer edge of submount 10 in each of the plurality of protruding portions 31a is denoted by Di (i is an integer, 1≤i≤n), a standard deviation of Di may be at most 50% of an average value of Di in the one side of the rectangle.

This configuration makes it possible to make the amounts of protrusion of the plurality of protruding portions 31a uniform, and to reduce variation in size of the plurality of protruding portions 31a. As a result, it is possible to prevent submount 10 from tilting. It should be noted that the standard deviation of Di is more preferably at most 20% of the average value of Di.

Specifically, as shown in FIG. 6, when the amount of protrusion of each of a plurality of protruding portions 31a on one shorter side (the top side in FIG. 6) of a pair of the shorter sides of rectangular submount 10 is denoted by DTi (1≤i≤n), a standard deviation of DTi may be at most 50% of an average value of DTi in the one shorter side. As an example, n=3, DT1=30 μm, DT2=80 μm, and DT3=40 μm, and an average value and a standard deviation in this case are 50 μm and 22 μm, respectively.

Moreover, when the amount of protrusion of each of a plurality of protruding portions 31a on a remaining one shorter side (the bottom side in FIG. 6) of the pair of the shorter sides of rectangular submount 10 is denoted by DBi (1≤i≤n), a standard deviation of DBi may be at most 50% of an average value of DBi in the remaining one shorter side. As an example, n=3, DB1=30 μm, DB2=50 μm, and DB3=40 μm, and an average value and a standard deviation in this case are 40 μm and 8 μm, respectively.

Furthermore, when the amount of protrusion of each of a plurality of protruding portions 31a on one longer side (the left side in FIG. 6) of a pair of the longer sides of rectangular submount 10 is denoted by DLi (1≤i≤n), a standard deviation of DLi may be at most 50% of an average value of DLi in the one longer side. As an example, n=5, DL1=60 μm, DL2=80 μm, DL3=50 μm, DL4=50 μm, and DL5=80 μm, and an average value and a standard deviation in this case are 64 μm and 14 μm, respectively.

Moreover, when the amount of protrusion of each of a plurality of protruding portions 31a on a remaining one longer side (the right side in FIG. 6) of the pair of the longer sides of rectangular submount 10 is denoted by DRi (1≤i≤n), a standard deviation of DRi may be at most 50% of an average value of DRi in the remaining one longer side. As an example, n=5, DR1=80 μm, DR2=60 μm, DR3=60 μm, DR4=80 μm, and DR5=70 μm, and an average value and a standard deviation in this case are 70 μm and 9 μm, respectively.

It should be noted that, with regard to amount of protrusion Di (1≤i≤n) of each of the plurality of protruding portions 31a, in one side of the rectangle, the maximum value and minimum value of Di may satisfy maximum value of Di/minimum value of Di≤3, and may more preferably satisfy maximum value of Di/minimum value of Di≤1.5. In this case also, it is possible to make the amounts of protrusion of the plurality of protruding portions 31a uniform, and to reduce variation in size of the plurality of protruding portions 31a. Additionally, in this case, since the amounts of protrusion of the plurality of protruding portions 31a are uniform in the one side of rectangular submount 10, it is possible to further prevent submount 10 from tilting.

Furthermore, in the case where the top view shape of submount 10 is an oblong as in the present embodiment, when a total number of a plurality of protruding portions 31a on the longer sides of the oblong is denoted by m, the amount of protrusion from the outer edge of submount 10 in each of a plurality of protruding portions 31a on one of the longer sides on the right side of an emission direction of laser light from semiconductor laser 20 is denoted by DRi (i is an integer, 1≤i≤n), and the amount of protrusion from the outer edge of submount 10 in each of a plurality of protruding portions 31a on a remaining one of the longer sides on the left side of the emission direction of the laser light from semiconductor laser 20 is denoted by DLi (i is an integer, 1≤i≤n), an average value of DRi and an average value of DLi may satisfy ⅓≤average value of DRi/average value of DLi≤3.

Since this makes it possible to reduce variation in size of the plurality of protruding portions 31a, it is possible to effectively prevent submount 10 from tilting. It should be noted that the average value of DRi and the average value of DLi may more preferably satisfy ½≤average value of DRi/average value of DLi≤2. Additionally, in this case also, it is more desirable that the amounts of protrusion of the plurality of protruding portions 31a be uniform in one side of rectangular submount 10.

Moreover, as shown in FIG. 3 and FIG. 4, in the case where semiconductor laser 20 is disposed closer to the left side of submount 10, when submount 10 on which semiconductor laser 20 is disposed is mounted on pedestal 3, pressure when submount 10 is pressed via semiconductor laser 20 is applied to the left side. Accordingly, the protrusion of solder between submount 10 and pedestal 3 is likely to be greater on the left side than on the right side. In other words, the amount of protrusion of protruding portions 31a on the left side is likely to be greater than the amount of protrusion of protruding portions 31a on the right side. As a result, there is a possibility that variation in size between protruding portions 31a on the left side and protruding portions 31a on the right side increases.

In view of the above, when semiconductor laser 20 is closer to the left side, an average value of DRi and an average value of DLi may satisfy ⅓≤average value of DRi/average value of DLi≤1, and may more preferably satisfy ⅓≤average value of DRi/average value of DLi≤¾. Since this makes it possible to reduce the difference in the amount of protrusion between protruding portions 31a on the left side and protruding portions 31a on the right side, it is possible to effectively prevent submount 10 from tilting.

Conversely, when semiconductor laser 20 is closer to the right side of submount 10, an average value of DRi and an average value of DLi may satisfy 1≤average value of DRi/average value of DLi≤3, and may more preferably satisfy 4/3≤average value of DRi/average value of DLi≤3. Since this makes it possible to reduce the difference in the amount of protrusion between protruding portions 31a on the left side and protruding portions 31a on the right side even when semiconductor laser 20 is closer to the right side of submount 10, it is possible to effectively prevent submount 10 from tilting.

Furthermore, in submount 10 whose top view shape is the rectangle, a total number of a plurality of protruding portions 31a on one side of the rectangle is denoted by n, and distances between the plurality of protruding portions 31a are each denoted by Pi (is an integer, 1≤i≤n−1), a standard deviation of Pi may be at most 20% of an average value of Pi.

Since this configuration makes it possible to make the distances between the plurality of protruding portions 31a uniform, it is possible to improve the symmetry of the plurality of protruding portions 31a by reducing variation in distance between the plurality of protruding portions 31a. As a result, it is possible to further prevent submount 10 from tilting. It should be noted that the standard deviation of Pi is more preferably at most 10% of the average value of Pi.

Specifically, as shown in FIG. 6, when distances between the plurality of protruding portions 31a on the one shorter side (the top side in FIG. 6) of the pair of the shorter sides of rectangular submount 10 are each denoted by PTi (1≤i≤n−1), a standard deviation of PTi may be at most 20% of an average value of PTi in the one shorter side. As an example, n=3 and PT1=PT2=130 μm.

Moreover, when distances between the plurality of protruding portions 31a on the remaining one shorter side (the bottom side in FIG. 6) of the pair of the shorter sides of rectangular submount 10 are each denoted by PBi (1≤i≤n−1), a standard deviation of PBi may be at most 20% of an average value of PBi in the remaining one shorter side. As an example, n=3 and PB1=PB2=130 μm.

Furthermore, when distances between the plurality of protruding portions 31a on the one longer side (the left side in FIG. 6) of the pair of the longer sides of rectangular submount 10 are each denoted by PLi (1≤i≤n−1), a standard deviation of PLi may be at most 20% of an average value of PLi in the one longer side. As an example, n=5 and PL1=PL2=PL3=PL4=140 μm.

Moreover, when distances between the plurality of protruding portions 31a on the remaining one longer side (the right side in FIG. 6) of the pair of the longer sides of rectangular submount 10 are each denoted by PRi (1≤i≤n−1), a standard deviation of PRi may be at most 20% of an average value of PRi in the one longer side. As an example, n=5 and PR1=PR2=PR3=PR4=140 μm.

It should be noted that, with regard to distance Pi (1≤i≤n−1) between the plurality of protruding portions 31a, in one side of the rectangle, the maximum value and minimum value of Pi may satisfy maximum value of Pi/minimum value of Pi≤3, and may more preferably satisfy maximum value of Pi/minimum value of Pi≤1.5. Since this makes it possible to make the distances between the plurality of protruding portions 31a more uniform, it is possible to further reduce variation in distance between the plurality of protruding portions 31a. Additionally, it is more desirable that the amounts of protrusion of the plurality of protruding portions 31a be uniform in one side of rectangular submount 10.

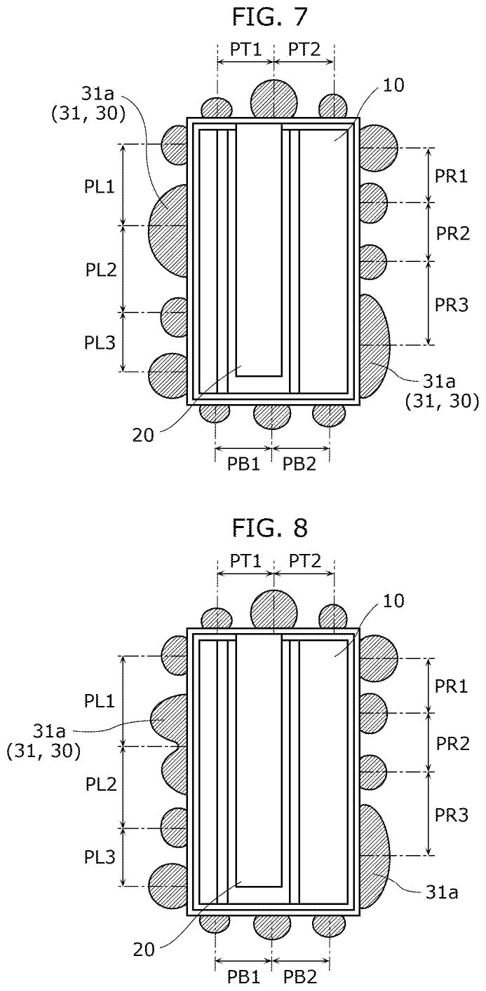

Moreover, although all protruding portions 31a do not comprise a portion obtained by combining two adjacent protruding portions 31a in FIG. 6, protruding portions 31a each obtained by combining two adjacent protruding portions 31a may be located as shown in FIG. 7 and FIG. 8.

In this case, the distances between the plurality of protruding portions 31a on the one side of submount 10 may include a group that includes a first distance having a standard deviation that falls within 10%, and a group that includes a second distance having a standard deviation that falls within 10%, and the second distance may be at most 1.5 times as much as the first distance.

From the above, it was confirmed that although the effect of preventing submount 10 from tilting became weaker than a case in which two adjacent protruding portions 31a are not combined as shown in FIG. 6, there was a certain level of effect of preventing submount 10 from tilting even when two adjacent protruding portions 31a were combined as shown in FIG. 7 and FIG. 8.

It should be noted that one protruding portion 31a obtained by combining two adjacent protruding portions 31a is in a protruding shape resulting from halving a spheroid as a whole in FIG. 7, and one protruding portion 31a obtained by combining two adjacent protruding portions 31a is in a shape resulting from connecting adjacent half-spheres smoothly via a portion therebetween in FIG. 8. In FIG. 7 and FIG. 8, the center position of one protruding portion 31a obtained by combining two adjacent protruding portions 31a on one side (a longer side in the figures) is in the vicinity of a midpoint between the centers of two protruding portions 31a prior to combining. As an example, distances between the plurality of protruding portions 31a shown in FIG. 7 and FIG. 8 are PT1=PT2=130 μm, PB1=PB2=130 μm, PL1=PL2=210 μm, PL3=140 μm, PR1=PR2=140 μm, and PR3=210 μm.

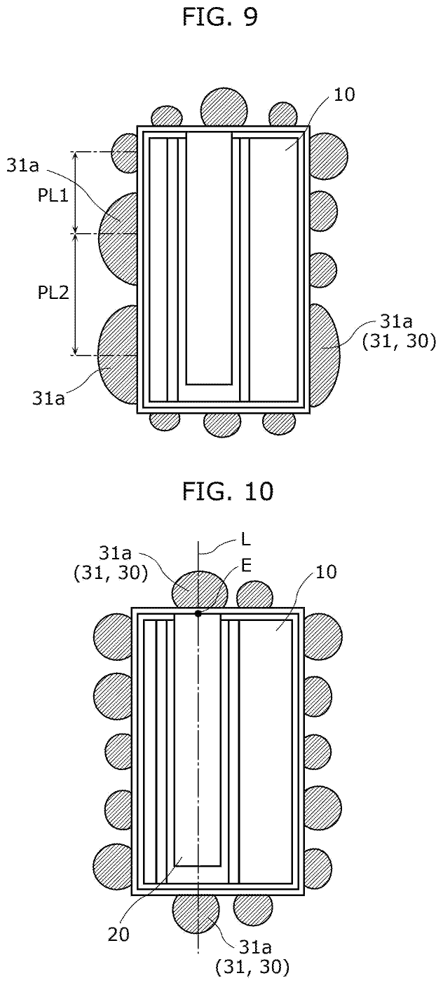

Furthermore, although a plurality of portions each of which is one protruding portion 31a obtained by combining two adjacent two protruding portions 31a are located, the plurality of portions are not adjacent to one another in FIG. 7 and FIG. 8. In some cases, portions each of which is one protruding portion 31a obtained by combining two adjacent protruding portions 31a are adjacent to one another as shown in FIG. 9.

In this case, the distances between the plurality of protruding portions 31a on the one side of submount 10 further include a group that includes a third distance that is different from the first distance and the second distance and has a standard deviation that falls within 10%, and the third distance may be at most twice as much as the first distance.

Accordingly, as shown in FIG. 9, even when portions each of which is one protruding portion 31a obtained by combining two adjacent protruding portions 31a are adjacent to each other, it is possible to prevent submount 10 from tilting. As an example, PL1=210 μm and PL2=280 μm in FIG. 9.

Moreover, since light-emission point E (a portion at which laser light is emitted) of semiconductor laser 20 has a high temperature due to a large amount of heat generation, as shown in FIG. 10, at least one of the plurality of protruding portions 31a may be located on optical axis L of semiconductor laser 20 in a top view.

Since this configuration causes at least one protruding portion 31a to be located immediately below light-emission point E of semiconductor laser 20, it is possible to efficiently dissipate the heat generated in semiconductor laser 20 via solder 30. Accordingly, it is possible to improve the thermal reliability of semiconductor laser device 1.

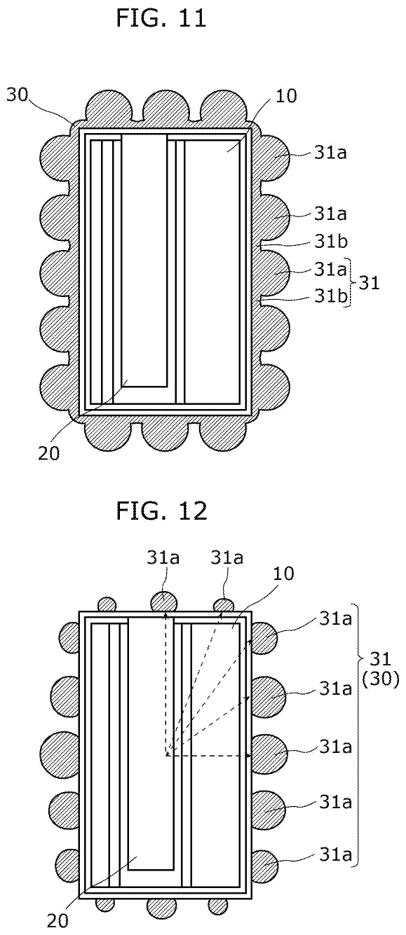

Furthermore, although non-protruding region 32, which is the region in which solder 30 does not protrude from the outer edge of submount 10, is located in protruding region 31 of solder 30 in FIG. 6 to FIG. 10, the present disclosure is not limited to this example. Specifically, as shown in FIG. 11, non-protruding region 32 need not be located in protruding region 31 of solder 30, and protruding region 31 may be located around the periphery of the outer edge of submount 10. In other words, solder 30 may protrude from the periphery of the outer edge of submount 10. In this case, protruding region 31 includes the plurality of protruding portions 31a and outer peripheral portion 31b, and the plurality of protruding portions 31a protrude in directions away from the inside of submount 10 and are located at regular intervals.

Moreover, although it is desirable that the amounts of protrusion of the plurality of protruding portions 31a in solder 30 be uniform, the amounts of protrusion of the plurality of protruding portions 31a in solder 30 need not be uniform. In this case, as shown in FIG. 12, the amounts of protrusion of the plurality of protruding portions 31a may decrease with an increase in distance from the center of submount 10 indicated by dashed arrows in a top view.

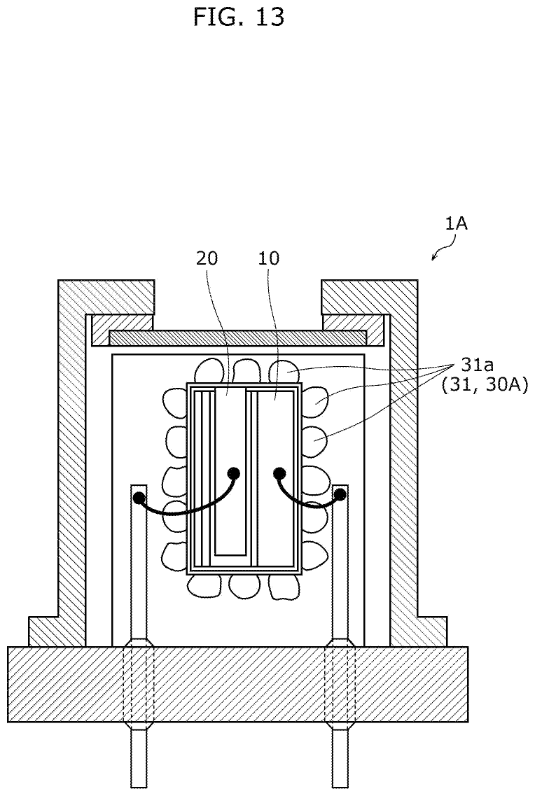

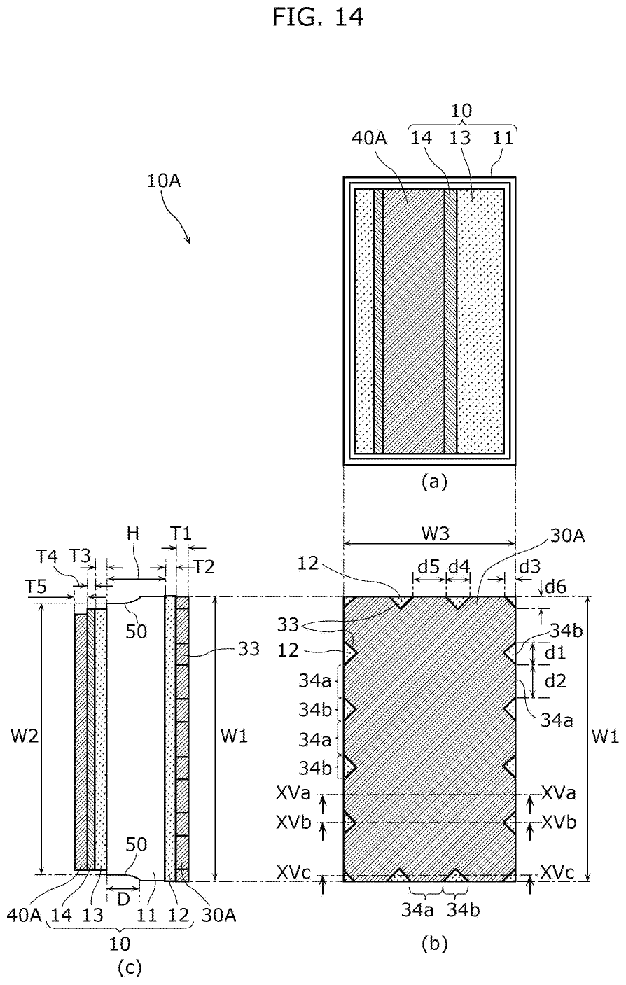

Furthermore, although the shapes of the plurality of protruding portions 31a in solder 30 are each a part of the sphere in semiconductor laser device 1 according to the present embodiment, the present disclosure is not limited to this example. For example, as in semiconductor laser device 1A shown in FIG. 13, a plurality of protruding portions 31a of solder 30 may each be in an irregular shape.

### [Method of Manufacturing Semiconductor Laser Device]

Hereinafter, a method of manufacturing semiconductor laser device 1 shown in FIG. 1 and FIG. 2 is described.

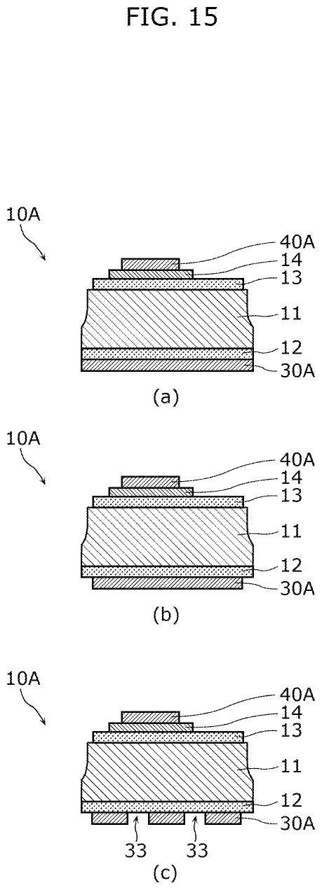

In semiconductor laser device 1 according to the present embodiment, submount 10 is joined to pedestal 3 using solder-provided submount 10A shown in FIG. 14 and FIG. 15. When submount 10 is joined to pedestal 3, solder-provided submount 10A is disposed on pedestal 3. In the present embodiment, a direction that corresponds to a side closer to pedestal 3 when solder-provided submount 10A is disposed on pedestal 3 is defined as a lower side (downward direction), and a direction that corresponds to a side opposite to the side closer to pedestal 3 (i.e., a side closer to semiconductor laser 20) is defined as an upper side (upward direction).

FIG. 14 is a view of a configuration of solder-provided submount 10A according to the present embodiment. In FIG. 14, (a) is a plan view when solder-provided submount 10A is viewed from a side closer to second solder layer 40A (front side: upper side), (b) is a plan view when solder-provided submount 10A is viewed from a side closer to first solder layer 30A (back side: lower side), and (c) is a cross-sectional view of solder-provided submount 10A. Moreover, FIG. 15 is a cross-sectional view of solder-provided submount 10A shown in FIG. 14. (a) in FIG. 15 is a cross-sectional view taken along line XVa-XVa in (b) in FIG. 14, (b) in FIG. 15 is a cross-sectional view taken along line XVb-XVb in (b) in FIG. 14, and (c) in FIG. 15 is a cross-sectional view taken along line XVc-XVc in (b) in FIG. 14.

Solder-provided submount 10A is obtained by providing solder layers in submount 10 in advance. As shown in FIG. 14 and FIG. 15, solder-provided submount 10A according to the present embodiment includes submount 10, first solder layer 30A, and second solder layer 40A.

When semiconductor laser device 1 is manufactured, first solder layer 30A is melted with heat to join submount 10 and pedestal 3. In other words, first solder layer 30A becomes solder 30 of semiconductor laser device 1 shown in FIG. 1.

When semiconductor laser device 1 is manufactured, second solder layer 40A is melted with heat to join submount 10 and semiconductor laser 20. In other words, second solder layer 40A becomes solder 40 of semiconductor laser device 1 shown in FIG. 1.

First solder layer 30A is disposed on a lower surface (bottom surface) of submount 10. Second solder layer 40A is disposed on an upper surface (top surface) of submount 10. To put it another way, submount 10 is interposed between first solder layer 30A and second solder layer 40A. First solder layer 30A and second solder layer 40A are each a solder layer that contains solder and has a certain thickness. In the present embodiment, first solder layer 30A and second solder layer 40A contain AuSn solder.

As stated above, submount 10 in solder-provided submount 10A includes insulative component 11, first metal film 12, second metal film 13, and barrier film 14.

As described above, insulative component 11 contains an insulative material such as diamond. In the present embodiment, step portions 50 are provided in upper portions of end surfaces of insulative component 11. Accordingly, a lower surface of insulative component 11 has a width greater than a width of an upper surface of insulative component 11.

First metal film 12 is disposed on the lower surface of insulative component 11. In contrast, second metal film 13 is disposed on the upper surface of insulative component 11. Barrier film 14 is provided on an upper surface of second metal film 13. As stated above, first metal film 12 and second metal film 13 may each be a Ti/Pt/Au stacked film. It should be noted that the plan view shape of first metal film 12 and second metal film 13 is a rectangle. In addition, barrier film 14 may be a Pt film.

First solder layer 30A is disposed on the lower surface of insulative component 11 of submount 10. In the present embodiment, first solder layer 30A is disposed on a lower surface (bottom surface) of first metal film 12. By providing first solder layer 30A on the bottom surface of first metal film 12, it is possible to improve solder wettability when first solder layer 30A is melted, and at the same time to improve the adhesiveness between submount 10 and pedestal 3.

Second solder layer 40A is disposed on an upper surface of insulative component 11 of submount 10. In the present embodiment, second solder layer 40A is disposed on an upper surface (top surface) of barrier film 14. By providing second solder layer 40A on the top surface of barrier film 14 that is the metal film, it is possible to improve solder wettability when second solder layer 40A is melted, and at the same time to improve the adhesiveness between submount 10 and semiconductor laser 20. Additionally, by providing barrier film 14, it is possible to prevent Sn from eroding an Au layer that is a surface layer of second metal film 13 when second solder layer 40A that contains AuSn solder is melted.

It should be noted that an example of the size of solder-provided submount 10A is as follows. Length W1 (the length of the longer side) in the longer-side direction of the bottom surface of submount 10 (insulative component 11) is 400 μm to 4000 μm, and is specifically set to 1200 μm. Moreover, since step portions 50 are provided in the upper portions of the end surfaces of solder-provided submount 10A, length W2 in the longer-side direction of the top surface of submount 10 (insulative component 11) is less than length W1 (W2<W1). For example, length W2 is 1150 μm. Length W3 (the length of the shorter side) in the shorter-side direction of the bottom surface of submount 10 (insulative component 11) is 200 μm to 600 μm, and is specifically set to 300 μm.

Thickness H of insulative component 11 is 270 μm to 330 μm, and is specifically set to 300 μm. Thickness T1 of first solder layer 30A is 4.5 μm to 8.0 μm before mounting and 2.0 μm to 3.5 μm after mounting, and is specifically 6.0 μm before mounting and 3.0 μm after mounting. Thickness T2 of first metal film 12 is 0.56 μm to 0.84 μm, and is specifically set to 0.70 μm. Thickness T3 of second metal film 13 is 0.56 μm to 0.84 μm, and is specifically set to 0.70 μm. Thickness T4 of barrier film 14 is 0.24 μm to 0.36 μm, and is specifically set to 0.30 μm. Thickness T5 of second solder layer 40A is 2.0 μm to 3.0 μm before mounting and 1.0 μm to 2.0 μm after mounting, and is specifically 2.5 μm before mounting and 1.5 μm after mounting.

In solder-provided submount 10A according to the present embodiment, opening portion 33 is provided in an outer peripheral edge portion of first solder layer 30A. Opening portion 33 is a region in which first solder layer 30A is not located. In other words, opening portion 33 is an opening of first solder layer 30A. A plurality of opening portions 33 are provided along the outer edge of first solder layer 30A.

Each opening portion 33 is provided to notch the outer peripheral edge portion of first solder layer 30A. In other words, in a plan view of first solder layer 30A, each opening portion 33 is a notch that recedes inwardly from the outer peripheral edge portion of insulative component 11. Specifically, in the plan view of first solder layer 30A, opening portion 33 is provided to recess a portion of a side of first solder layer 30A. In the present embodiment, the shape of opening portion 33 provided on one side of first solder layer 30A is a triangle. As an example, the shape of opening portion 33 provided on one side of first solder layer 30A is an isosceles triangle in which the bottom of opening portion 33 (a portion receding most from the side) is a vertex angle that is the right angle in the plan view of first solder layer 30A, and the shape of opening portion 33 provided in a corner of first solder layer 30A is an isosceles triangle formed by chamfering in the plan view of first solder layer 30A. It should be noted that it is possible to provide first solder layer 30A including opening portions 33 by lift-off of solder using a resist.

By providing opening portions 33 in first solder layer 30A, first metal film 12 is exposed from opening portions 33. Accordingly, since the plurality of opening portions 33 are intermittently located in the outer peripheral portion of first solder layer 30A, the outer edge of the lower surface (bottom surface) of first metal film 12 includes a portion in which first region 34a in which first solder layer 30A is located and second region 34b in which first solder layer 30A is not located are alternately located. To put it another way, a plurality of first regions 34a and a plurality of second regions 34b are located in the outer edge of first metal film 12. The outer edge of a lower surface of first metal film 12 in opening portions 33 includes second regions 34b.

Opening portions 33 may be located on all the four sides of first solder layer 30A or may be located on one side, two sides, or three sides among the four sides. As a result, second regions 34b corresponding to opening portions 33 may be located on all the four sides of the outer edge of first metal film 12 or may be located on one side, two sides, or three sides among the four sides. In the present embodiment, opening portions 33 and second regions 34b are provided on all the four sides of first solder layer 30A and all the four sides of first metal film 12.

All opening portions 33 provided in first solder layer 30A comprise a plurality of opening portions 33 located at regular intervals. Since opening portions 33 correspond to second regions 34b in which first solder layer 30A is not located, all second regions 34b located in the outer edge of the bottom surface of first metal film 12 comprise a plurality of second regions 34b located at regular intervals.

The plurality of opening portions 33 located at regular intervals may be located on all the four sides of first solder layer 30A or may be located on one side, two sides, or three sides among the four sides. In other words, the plurality of second regions 34b located at regular intervals may be located on all the four sides of the outer edge of the bottom surface of first metal film 12 or may be located on one side, two sides, or three sides among the four sides.

Moreover, the plurality of opening portions 33 (second regions 34b) located at regular intervals may be all opening portions 33 (second regions 34b) on the one side or may be some of all opening portions 33 (second regions 34b) on the one side. As stated above, the plurality of opening portions 33 (second regions 34b) located at regular intervals may be located on at least a portion of the periphery of first solder layer 30A or first metal film 12.

It should be noted that the expression “a plurality of opening portions 33 (second regions 34b) are located at regular intervals” includes not only a case in which a plurality of opening portions 33 (second regions 34b) are located at a certain distance from one another but also a case in which a plurality of opening portions 33 (second regions 34b) are located at a regular distance from one another.

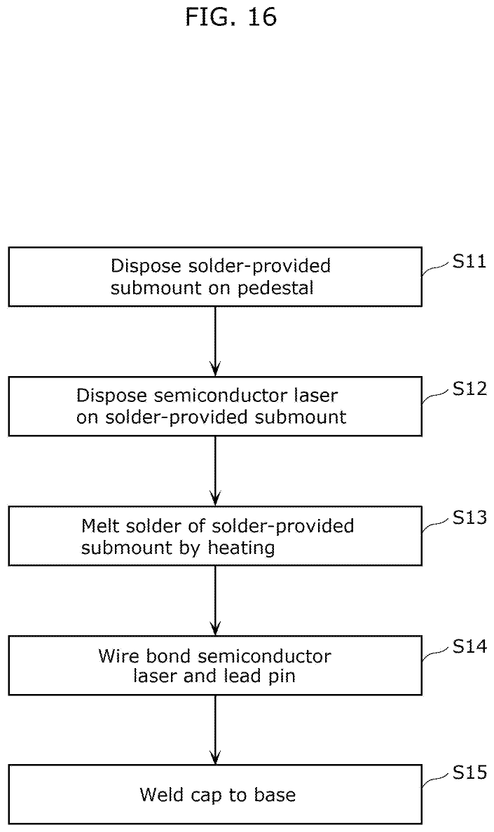

Hereinafter, a method of manufacturing semiconductor laser device 1 using solder-provided submount 10A is described with reference to FIG. 16 in addition to FIG. 1 to FIG. 4 and FIG. 14 etc. FIG. 16 is a flow chart illustrating a method of manufacturing semiconductor laser device 1 according to the present embodiment.

First, solder-provided submount 10A is disposed on pedestal 3 of a stem with electrode terminals that includes base 2 to which lead pins 4 and pedestal 3 shown in FIG. 1 and FIG. 2 are attached (step S11). At this time, solder-provided submount 10A is disposed on pedestal 3 to orient first solder layer 30A to pedestal 3. Specifically, solder-provided submount 10A is disposed to cause first solder layer 30A to be in contact with pedestal 3.

Next, semiconductor laser 20 is disposed on solder-provided submount 10A shown in FIG. 14 (step S12). Specifically, semiconductor laser 20 is disposed on second solder layer 40A of solder-provided submount 10A. It should be noted that, in the present embodiment, semiconductor laser 20 is disposed on solder-provided submount 10A by junction down mounting.

Then, the solder of solder-provided submount 10A is melted with heat (step S13). Specifically, solder-provided submount 10A is heated while semiconductor laser 20 disposed on solder-provided submount 10A is pressed down from above. As an example, heating is performed at a temperature of 330° C. for approximately 10 seconds.

First solder layer 30A and second solder layer 40A are melted by heating solder-provided submount 10A as above. Accordingly, pedestal 3 and submount 10 are joined with the molten solder of first solder layer 30A, and at the same time semiconductor laser 20 and submount 10 are joined with the molten solder of second solder layer 40A.

In the present embodiment, since first solder layer 30A and second solder layer 40A contain the same solder material, it is possible to join semiconductor laser 20, submount 10, and pedestal 3 simultaneously.

Moreover, in the present embodiment, since solder-provided submount 10A is heated while semiconductor laser 20 is pressed down, submount 10 is pressed toward pedestal 3. In other words, submount 10 applies the pressing force toward pedestal 3. For this reason, the pressing force of submount 10 causes the molten solder of first solder layer 30A located between submount 10 and pedestal 3 to protrude from submount 10. Specifically, the molten solder of first solder layer 30A expands from the outer edge of submount 10 toward the outside, and at the same time extends in a thickness direction of submount 10. To put it another way, the molten solder of first solder layer 30A extends in a direction horizontal to the mounting surface of pedestal 3 for submount 10, and at the same time also extends above pedestal 3 in the lateral sides of submount 10.

At this time, the molten solder of first solder layer 30A protrudes from the outer edge of submount 10 with regions in which solder is located in the outer peripheral portion of first solder layer 30A as starting points. In contrast, since opening portions 33 are intermittently provided in the outer peripheral portion of first solder layer 30A in the present embodiment, the outer peripheral portion of first solder layer 30A includes regions in which solder is located and regions in which solder is not located.

Specifically, as shown in FIG. 14, the outer edge of the bottom surface of first metal film 12 includes a portion in which first region 34a including first solder layer 30A and second region 34b not including first solder layer 30A are alternately located. For this reason, the molten solder of first solder layer 30A protrudes from the outer edge of submount 10 with first region 34a, which includes first solder layer 30A, as a starting point.

Although the length of second region 34b, which does not include first solder layer 30A, along the outer edge of submount 10 decreases (i.e., opening portion 33 is gradually filled with the solder) as the protrusion of the solder progresses, the surface tension of the molten solder prevents the solder from protruding from second region 34b (opening portion 33), which does not include first solder layer 30A prior to melting, toward the outside of submount 10. In other words, the solder is prevented from protruding, toward the outside of submount 10, from a region other than a region in which first solder layer 30A prior to melting is located, in the outer edge of submount 10. As a result, the solder of first solder layer 30A, which protrudes from the outer edge of submount 10, becomes protruding region 31 in the shape shown in FIG. 3 and FIG. 4. Specifically, after cooling, the molten solder of first solder layer 30A becomes solder 30 in a shape formed by providing a plurality of protruding portions 31a in protruding region 31 as shown in FIG. 3 and FIG. 4.

At this time, in the present embodiment, as shown in FIG. 14, opening portions 33 of first solder layer 30A comprise a plurality of opening portions 33 located at regular intervals. In other words, second regions 34b (regions not including first solder layer 30A) located in the outer edge of the bottom surface of first metal film 12 comprise a plurality of second regions 34b located at regular intervals. As a result, protruding region 31 of solder 30 includes a plurality of protruding portions 31a located at regular intervals. Since the plurality of protruding portions 31a are located at regular intervals, solder 30 protrudes without solder 30 being non-uniform, and it is possible to join submount 10 to pedestal 3 without submount 10 tilting.

It should be noted that it is possible to determine the tilt of submount 10 by measuring a state of the plurality of protruding portions 31a in solder 30. Accordingly, at this time, a test to make a pass/fail assessment may be performed by estimating the tilt of submount 10. This testing method is described in detail later.

After that, semiconductor laser 20 and lead pins 4 are wire bonded (step S14). Specifically, one of the pair of electrodes of semiconductor laser 20 and one of the pair of lead pins 4 are connected with gold wire 7, and at the same time second metal film 13 of submount 10 and a remaining one of the pair of lead pins 4 are connected with gold wire 7.

Finally, cap 5 is welded to base 2 (step S15). Specifically, after semiconductor laser 20 and lead pins 4 are wire bonded, UV irradiation ozone cleaning is performed, and subsequently cap 5 is disposed on base 2, and base 2 and cap 5 are joined by welding base 2 and cap 5.

Accordingly, semiconductor laser device 1 of the TO-CAN package type shown in FIG. 1 and FIG. 2 is completed.

Here, a desirable form of first solder layer 30A in solder-provided submount 10A is described with reference to FIG. 14.

First, as shown in (b) in FIG. 14, in the plan view of first solder layer 30A, the length (d2, d5 in FIG. 14) of first region 34a in the outer edge of the lower surface of first metal film 12 may be at least 20 μm and at most 200 μm.

Since first region 34a is a region including first solder layer 30A, first region 34a is a region to be a starting point when the solder of first solder layer 30A is melted and the molten solder protrudes from submount 10.

Here, in the case where first region 34a is excessively large in length, there is a possibility that when the solder of first solder layer 30A is melted and expands toward the outside of submount 10, a border between submount 10 and a protruding region (protruding portion 31a) of the solder becomes excessively large in length. In other words, there is a possibility that a root of protruding portion 31a of solder 30 becomes excessively large in width and that the amount of protrusion of the solder of protruding portion 31a partially increases too much. As stated above, when the root of protruding portion 31a becomes excessively large in width, there is a possibility that a symmetry of protruding region 31 (protruding portion 31a) of solder 30 is broken and submount 10 joined with solder 30 tilts. In view of the above, the length of first region 34a may be at most 200 μm. This makes it possible to prevent the root of protruding portion 31a from becoming excessively large in width, and prevent submount 10 from tilting.

On the other hand, in the case where first region 34a is excessively small in length, there is a possibility that when the solder of first solder layer 30A is melted, the molten solder does not readily protrude from first region 34a of submount 10, and a place to go for the molten solder is limited. At this time, there is a possibility that the solder for which the place to go is limited expands into second region 34b (a region not including first solder layer 30A), and the molten solder protrudes from second region 34b toward the outside of submount 10 instead of protruding from first region 34a (the region including first solder layer 30A) toward the outside of submount 10. As stated above, there is a possibility that the protrusion of the solder from second region 34b breaks the symmetry of protruding region 31 (protruding portion 31a) of solder 30, and submount 10 joined with solder 30 tilts. In view of the above, the length of first region 34a may be at least 20 μm. This makes it possible to prevent the molten solder from protruding from second region 34b toward the outside, and prevent submount 10 from tilting.

As an example, in rectangular submount 10, length d2 of first region 34a on a longer side is 80 μm, and length d5 of first region 34a on a shorter side is 80 μm. It should be noted that although length d2 of first region 34a on the longer side and length d5 of first region 34a on the shorter side are equal in the present embodiment, the present disclosure is not limited to this example. In this case, length d5 of first region 34a on the shorter side may be greater than length d2 of first region 34a on the longer side (d5>d2). This makes it possible to equalize the amount of protrusion of protruding portion 31a protruding from the longer side and the amount of protrusion of protruding portion 31a protruding from the shorter side.

Moreover, as shown in (b) in FIG. 14, in the plan view of first solder layer 30A, the length (d1, d4 in FIG. 14) of second region 34b in the outer edge of the lower surface of first metal film 12 may be at least 20 μm and at most 200 μm.

As stated above, by setting the length of second region 34b to at most 200 μm, when the solder of first solder layer 30A is melted and protrudes from a plurality of first regions 34a toward the outside of submount 10, it is possible to prevent solder (a plurality of protruding portions 31a) protruding from each of the plurality of first regions 34a from becoming too discrete. When the protruding solder becomes discrete, the number of protruding portions decreases, and differences in size among protruding portions 31a readily break the symmetry of the amounts of protrusion.

Accordingly, when the protruding solder does not become excessively discrete, it is possible to prevent submount 10 joined with solder 30 from tilting. Additionally, by setting the length of second region 34b to at least 20 μm, when the solder of first solder layer 30A is melted and protrudes from a plurality of first regions 34a toward the outside of submount 10, it is possible to prevent solder protruding from each of the plurality of first regions 34a from integrating upon contact with one another. To put it another way, it is possible to prevent two adjacent protruding portions 31a from integrating upon contact with each other.

As an example, in rectangular submount 10, length d1 of second region 34b on a longer side is 60 μm, and length d4 of second region 34b on a shorter side is 50 μm. It should be noted that although length d1 of second region 34b on the longer side and length d4 of second region 34b on the shorter side are different from each other in the present embodiment, length d1 may be equal to length d4. In addition, when length d1 of second region 34b on the longer side and length d4 of second region 34b on the shorter side are different from each other, length d1 of second region 34b on the longer side may be greater than length d4 of second region 34b on the shorter side as in the present embodiment. This makes it possible to equalize the amount of protrusion of protruding portion 31a protruding from the longer side and the amount of protrusion of protruding portion 31a protruding from the shorter side.

Furthermore, as shown in (b) in FIG. 14, in the plan view of first solder layer 30A, a length (d3, d6 in FIG. 14) between one end portion of opening portion 33 and an other end portion of opening portion 33 opposite to the one end in the outer peripheral edge portion of insulative component 11 may be at least 20 μm and at most 100 μm. In other words, the amount of recession of opening portion 33 obtained by notching to recede inwardly from the outer peripheral edge portion of insulative component 11 may be at least 20 μm and at most 100 μm.

As stated above, by setting the amount of recession of opening portion 33 to at least 20 μm, when the solder of first solder layer 30A is melted, it is possible to prevent the molten solder from protruding from second region 34b (the region not including first solder layer 30A) toward the outside of submount 10. Additionally, by setting the amount of recession of opening portion 33 to at most 100 μm, it is possible to prevent a portion (void) in which solder is not located between submount 10 and pedestal 3 from being provided in an inner region of submount 10 (insulative component 11). Since this makes it possible to prevent the void from being provided in solder 30, it is possible to prevent heat dissipation for heat generated in semiconductor laser 20 from deteriorating.

As an example, in rectangular submount 10, length d3 of the amount of recession of opening portion 33 from a longer side is 30 μm, and length d6 of the amount of recession of opening portion 33 from a shorter side is 30 μm. It should be noted that although length d3 and length d6 are equal in the present embodiment, length d3 and length d6 may be different from each other.

Moreover, as shown in (b) in FIG. 14, in one side of the outer edge of rectangular submount 10 (insulative component 11), a length of first region 34a in the central portion of the one side may be less than a length of first region 34a in a portion closest to an end portion of the one side.

When submount 10 and pedestal 3 are joined to semiconductor laser 20, a load is applied to the center of semiconductor laser 20. At this time, when a plurality of first regions 34a on one side of first solder layer 30A have the same length and second regions 34b are located at a regular distance from each other, the size of solder (protruding portions 31a) protruding from submount 10 decreases with an increase in distance to an end portion of submount 10. In view of the above, by causing the length of first region 34a located at the central portion of the one side of first solder layer 30A to be less than the length of first region 34a located at the portion closest to the end portion, it is possible to make the size of the solder (protruding portions 31a) protruding from submount 10 uniform. This makes it possible to make the amounts of protrusion of a plurality of protruding portions 31a protruding from submount 10 in the one side of submount 10 uniform. As a result, it is possible to prevent submount 10 joined with solder 30 from tilting.

In this case, the lengths of the plurality of first regions 34a on the one side of first solder layer 30A may be gradually increased in order of increasing distance from the central portion to the end portion. For example, five first regions 34a are located on a longer side of first solder layer 30A in (a) in FIG. 14; and the length of central first region 34a may be made least (e.g., 40 μm), the lengths of two first regions 34a at both ends may be made greatest (e.g., 80 μm), and the length of each of two first regions 34a located halfway between central first region 34a and a corresponding one of two first regions 34a at both ends may be made intermediate (e.g., 60 μm).

It should be noted that although the shape (opening shape) of opening portions 33 provided in first solder layer 30A is a triangle in solder-provided submount 10A according to the present embodiment, the present disclosure is not limited to this example.

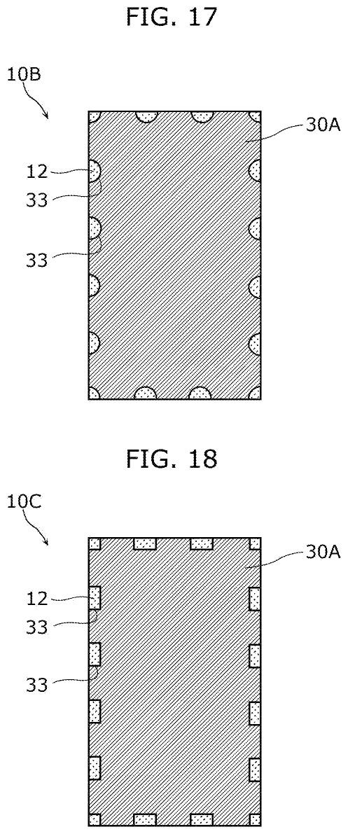

For example, as in solder-provided submount 10B shown in FIG. 17, the shape of opening portions 33 provided in first solder layer 30A may be a semicircle. By setting the shape of opening portions 33 to the semicircle as above, it is possible to facilitate the lift-off of the solder resist.

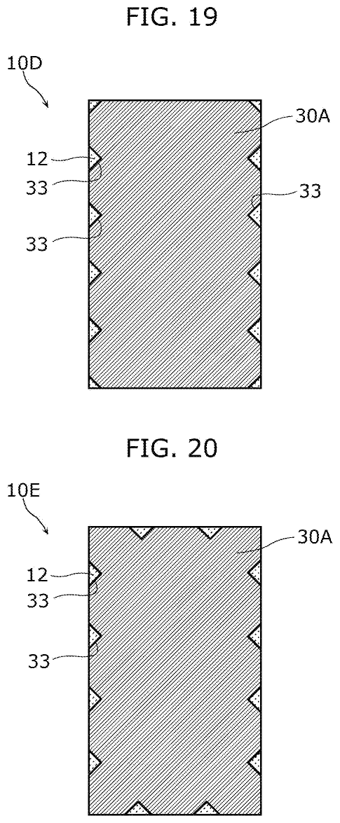

Furthermore, as in solder-provided submount 10C shown in FIG. 18, the shape of opening portions 33 provided in first solder layer 30A may be a rectangle. By setting the shape of opening portions 33 to the rectangle as above, as will be described later, when solder-provided submount 10A is manufactured by dividing a solder-provided submount assembly, it is possible to reduce a variation in opening width for displacement at the time of the dividing, and to reduce a variation in element among solder-provided submounts 10A.

It should be noted that, from a point of view of providing a plurality of protruding portions 31a of solder 30 at regular intervals, the shape of opening portions 33 of first solder layer 30A may be a triangle. The difficulty of protrusion when the molten solder of first solder layer 30A protrudes toward the outside of submount 10 depends on the shape of opening portions 33. By setting the shape of opening portions 33 to a triangle, the molten solder is prevented from filling opening portions 33 and protruding from second regions 34b toward the outside of submount 10, compared to a case in which the shape of opening portions 33 is a semicircle or a rectangle. As a result, it is possible to stably provide protruding portions 31a at regular intervals.

Furthermore, positions of opening portions 33 of first solder layer 30A are also not limited to the positions shown in (b) in FIG. 14.

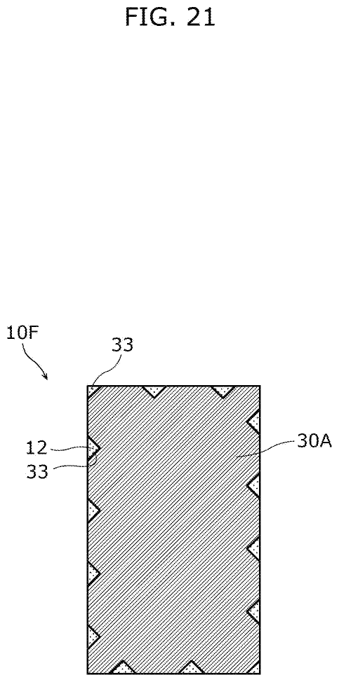

For example, as in solder-provided submount 10D shown in FIG. 19, opening portions 33 of first solder layer 30A may be provided only on, among shorter sides and longer sides, the longer sides. Since submount 10 is likely to tilt in a shorter-side direction, even when protruding portions 31a are not provided on the shorter sides, it is possible to prevent submount 10 from tilting as long as protruding portions 31a are provided at regular intervals only on the longer sides.

Moreover, as in solder-provided submount 10E shown in FIG. 20, opening portions 33 of first solder layer 30A need not be provided in corner portions of first solder layer 30A. Since the molten solder of first solder layer 30A protrudes from corner portions farthest from the center, even when opening portions 33 are not provided in the corner portions of first solder layer 30A, it is possible to provide a plurality of protruding portions 31a equal in size as a whole. Additionally, in the case where solder-provided submount 10E is manufactured by dividing a solder-provided submount assembly, it is possible to make the shape of division surfaces linear when solder is not located in the corner portions of first solder layer 30A.

Furthermore, as in solder-provided submount 10F shown in FIG. 21, a plurality of corner portions of first solder layer 30A may be configured to alternately include a corner portion in which opening portion 33 is provided and a corner portion in which opening portion 33 is not provided. When semiconductor laser 20 is mounted in a position that is offset relative to the center of submount 10 in a width direction, this configuration makes it easy to dispose first region 34a immediately below a light-emission point of semiconductor laser 20, and makes it possible to improve heat dissipation for heat generated in semiconductor laser 20.

It should be noted that although opening portions 33 of first solder layer 30A are not provided in a bilaterally symmetrical manner or a vertically symmetrical manner in FIG. 19 to FIG. 21, it is possible to prevent submount 10 from tilting by manufacturing a semiconductor laser device using solder-provided submount 10F.

### [Solder-Provided Submount Assembly]

Although it is possible to manufacture above-described solder-provided submounts 10A to 10F on a one-by-one basis, it is also possible to manufacture solder-provided submounts 10A to 10F by dividing one solder-provided submount assembly into parts.

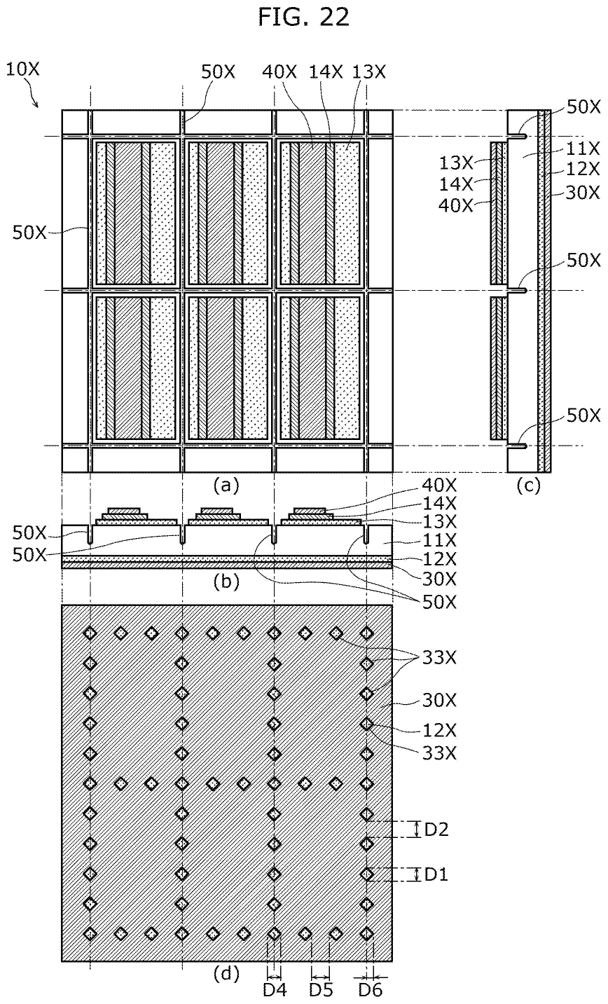

Hereinafter, such solder-provided submount assembly 10X is described with reference to FIG. 22. FIG. 22 is a view of a configuration of solder-provided submount assembly 10X according to the present embodiment. In FIG. 22, (a) is a top view, (b) and (c) are side views, and (d) is a rear view.

Solder-provided submount assembly 10X is an aggregate of solder-provided submounts. It is possible to obtain a plurality of solder-provided submounts by dividing solder-provided submount assembly 10X into parts.

As shown in FIG. 22, solder-provided submount assembly 10X includes substrate 11X, first metal film 12X, second metal film 13X, barrier film 14X, first solder layer 30X, and second solder layer 40X.

Grooves 50X in a lattice pattern are provided on an upper surface of solder-provided submount assembly 10X. Grooves 50X are provided on substrate 11X. Specifically, grooves 50X are provided by digging substrate 11X from the top surface toward the bottom surface.

Substrate 11X is an insulating substrate that contains an insulative material. Substrate 11X becomes insulative component 11 of submount 10. Accordingly, substrate 11X contains the same material as insulative component 11.

First metal film 12X is disposed on a lower surface of substrate 11X. First metal film 12X is provided across grooves 50X in the lattice pattern on the entire lower surface of substrate 11X. First metal film 12X contains the same material as first metal film 12 of submount 10.

Second metal film 13X is disposed on an upper surface of substrate 11X. In a top view, second metal film 13X is provided for each of a plurality of frames of grooves 50X in the lattice pattern. Second metal film 13X contains the same material as second metal film 13 of submount 10.

Barrier film 14X is provided on an upper surface of each second metal film 13X. In the top view, barrier film 14X is provided for each of the plurality of frames of grooves 50X in the lattice pattern. Barrier film 14X contains the same material as barrier film 14 of submount 10.

First solder layer 30X is disposed on a lower side of substrate 11X. In the present embodiment, first solder layer 30X is disposed on a lower surface of first metal film 12X. As with first metal film 12X, first solder layer 30X is provided across grooves 50X in the lattice pattern on the entire lower surface of first metal film 12X. First solder layer 30X contains the same material as first solder layer 30A of solder-provided submount 10A. In other words, first solder layer 30X contains the same material as solder 30 of semiconductor laser device 1.

Second solder layer 40X is disposed on an upper side of substrate 11X. In the present embodiment, second solder layer 40X is disposed on an upper surface of each barrier film 14X. In the top view, second solder layer 40X is provided for each of the plurality of frames of grooves 50X in the lattice pattern. Second solder layer 40X contains the same material as second solder layer 40A of solder-provided submount 10A. To put it another way, second solder layer 40X contains the same material as solder 40 of semiconductor laser device 1.

In solder-provided submount assembly 10x, a plurality of opening portions 33X are provided in first solder layer 30X. Each of the plurality of opening portions 33X is a region not including first solder layer 30X. The plurality of opening portions 33X are provided at positions immediately below grooves 50X. In addition, the plurality of opening portions 33X are provided at regular intervals. Accordingly, portions in each of which regions not including first solder layer 30X are located at regular intervals are located at the positions immediately below grooves 50X. Specifically, the plurality of opening portions 33X are provided corresponding to grooves 50X in the lattice pattern to cause a plurality of perforated straight lines (dashed lines) to be at right angles to one another. It should be noted that, as an example, the shape of one opening portion 33X is a rectangular shape. In this case, the plurality of opening portions 33X are arranged to cause corner portions of two adjacent rectangular opening portions 33X to face each other.

By providing opening portions 33X in first solder layer 30X, first metal film 12X is exposed from opening portions 33X. Accordingly, since the plurality of opening portions 33X are located at regular intervals in first solder layer 30X at the positions immediately below grooves 50x, the region including first solder layer 30X and the region not including first solder layer 30X are alternately located at regular intervals on the lower surface of first metal film 12X.

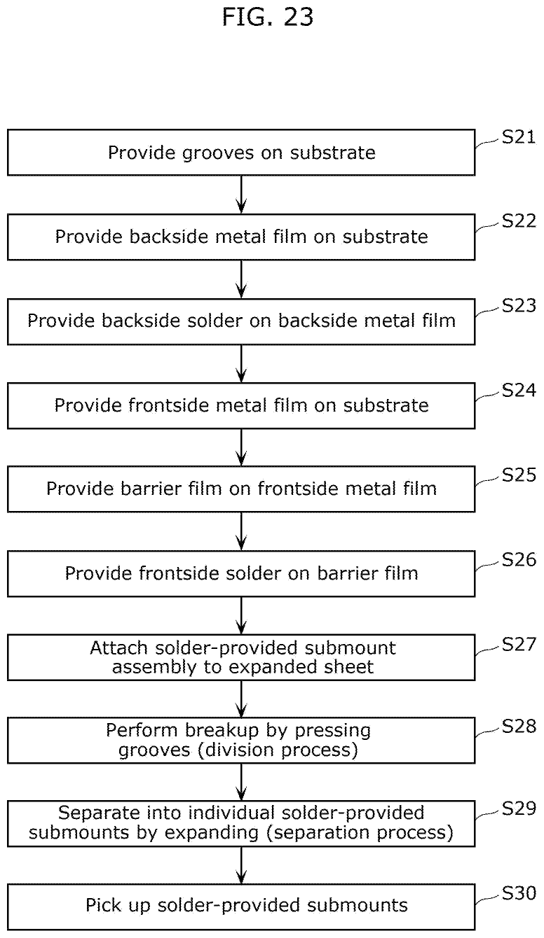

Next, referring to FIG. 22, a method of manufacturing solder-provided submount 10A using solder-provided submount assembly 10X shown in FIG. 22 is described with reference to FIG. 23. FIG. 23 is a flow chart illustrating a method of manufacturing solder-provided submount 10A according to the present embodiment.

First, grooves 50X in a lattice pattern are provided on substrate 11X (step S21). Specifically, as shown in FIG. 22, grooves 50X are provided by digging substrate 11X from the top surface toward the bottom surface. It is possible to use a diamond substrate, a SiC substrate, or an AlN substrate as substrate 11X. In this case, laser processing, rotary blade processing, or etching (wet etching, dry etching) makes it possible to provide grooves 50X in the lattice pattern on substrate 11X. It should be noted that although grooves 50X are provided in a contiguously linear manner, grooves 50X may be provided in a dashed linear manner.

Next, a backside metal film is provided on substrate 11X (step S22). Specifically, as shown in FIG. 22, first metal film 12X is provided as the backside metal film on a lower surface of substrate 11X. As an example, a stacked film including three layers of T1/Pt/Au is provided as first metal film 12X by vapor deposition. First metal film 12X becomes a solder foundation layer of first solder layer 30X.

Then, backside solder is provided on the backside metal film (step S23). Specifically, as shown in FIG. 22, first solder layer 30X is provided as the backside solder on a lower surface of first metal film 12X that is the backside metal film. At this time, as shown in FIG. 22, first solder layer 30X that includes a plurality of opening portions 33X located at positions immediately below grooves 50X in the lattice pattern is provided.

In this case, for example, a backside resist is patterned on the surface of first metal film 12X, solder such as AuSn solder is provided by vapor deposition, and subsequently the backside resist is separated. This makes it possible to provide first solder layer 30X including the plurality of opening portions 33X.

After that, a frontside metal film is provided on substrate 11X (step S24). Specifically, as shown in FIG. 22, second metal film 13X is provided as the frontside metal film on an upper surface of substrate 11X. As an example, a stacked film including three layers of T1/Pt/Au is provided as second metal film 13X by vapor deposition. Second metal film 13X becomes a solder foundation layer of second solder layer 40X.

Next, barrier film 14X is provided on the frontside metal film (step S25). Specifically, as shown in FIG. 22, barrier film 14X is provided on an upper surface of second metal film 13X that is the frontside metal film. As an example, a frontside resist is patterned, a platinum film is provided by vapor deposition, and subsequently the frontside resist is separated. This makes it possible to provide barrier film 14X for each of frames of grooves 50X in the lattice pattern.

Then, frontside solder is provided on barrier film 14X (step S26). Specifically, as shown in FIG. 22, second solder layer 40X is provided as the frontside solder on an upper surface of barrier film 14X. Specifically, a frontside resist is patterned on the entire surface of substrate 11X to cover barrier film 14X, solder such as AuSn solder is provided by vapor deposition, and subsequently the frontside resist is separated. This makes it possible to provide second solder layer 40X for each of the frames of grooves 50X in the lattice pattern.

Accordingly, as shown in FIG. 22, it is possible to manufacture solder-provided submount assembly 10X on which grooves 50X are provided.

After that, solder-provided submount assembly 10X is attached to an expanded sheet (step S27). The expanded sheet is a stretchable sheet having adhesiveness. Specifically, solder-provided submount assembly 10X is disposed on the expanded sheet. Accordingly, solder-provided submount assembly 10X is attached to the expanded sheet due to an adhesive layer of the expanded sheet.

Next, a breakup is performed by pressing grooves 50X of solder-provided submount assembly 10X (step S28). Specifically, grooves 50X are pressed from a back surface of the expanded sheet. Accordingly, solder-provided submount assembly 10X is divided along grooves 50X that serve as division lines into parts. In this case, for example, groove 50X on a side closer to a longer side is initially pressed, and groove 50X on a side closer to a shorter side is subsequently pressed. It should be noted that a rubber component may be used as a tray on the side closer to the shorter side, and a stainless component may be used as a tray on the side closer to the longer side.

In addition, at this time, the plurality of opening portions 33X located at the positions immediately below grooves 50X are also divided. Specifically, rectangular opening portion 33X is divided into two triangular opening portions 33.

As stated above, by providing grooves 50X in the lattice pattern (division lines), it is possible to divide first solder layer 30X including the plurality of opening portions 33X readily. In other words, there is a possibility that when it is intended to divide first solder layer 30X without providing grooves 50X, only substrate 11X is divided due to softness of the solder in first solder layer 30X, and first solder layer 30X is not divided. In contrast, by providing grooves 50X to face the plurality of opening portions 33X, breaking up solder-provided submount assembly 10X makes it possible to divide first solder layer 30X along grooves 50X readily.

It should be noted that the depth of grooves 50X may be at least ¼ and at most ¾ of the thickness of substrate 11X. When the depth of grooves 50X is less than ¼ of the thickness of substrate 11X, there is a possibility that solder-provided submount assembly 10X is not successfully divided. On the other hand, when the depth of grooves 50X exceeds ¾ of the thickness of substrate 11X, there is a possibility that solder-provided submount assembly 10X cracks when handled. To put it another way, handling properties of solder-provided submount assembly 10X deteriorate.

In the present embodiment, the depth of grooves 50X is set to approximately ½ of the thickness of substrate 11X.

Then, separation into individual solder-provided submounts 10A is performed by expanding the expanded sheet (step S29). Accordingly, solder-provided submount assembly 10X divided along grooves 50X is separated into the plurality of solder-provided submounts 10A.

It should be noted that even when first solder layer 30X includes an undivided portion when solder-provided submount assembly 10X is broken up, it is also possible to divide the undivided portion at the time of the breakup, by expanding the expanded sheet to which solder-provided submount assembly 10X is attached. Accordingly, it is possible to prevent solder-provided submounts 10A to be separated from remaining unseparated (i.e., the occurrence of twins).

Finally, solder-provided submounts 10A are picked up (step S30). For example, the plurality of solder-provided submounts 10A separated on the expanded sheet are picked up by pushing up the plurality of solder-provided submounts 10A one-by-one from a back side of the expanded sheet using push-up pins.

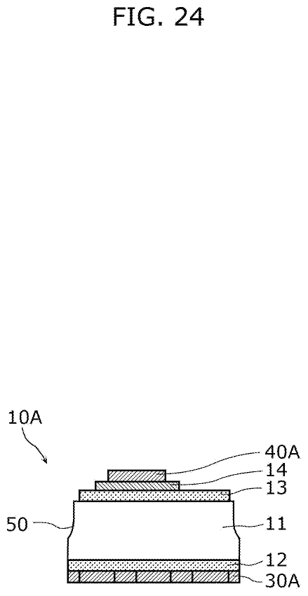

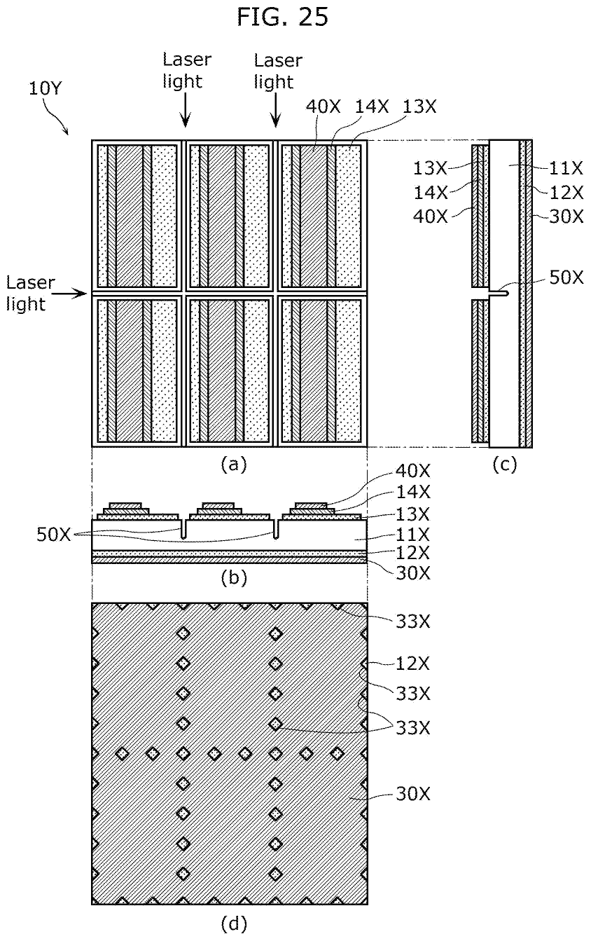

Accordingly, it is possible to obtain solder-provided submount 10A shown in FIG. 24. Specifically, it is possible to obtain solder-provided submount 10A including step portions 50 corresponding to grooves 50X. In other words, groove 50X of solder-provided submount assembly 10X is separated into two parts, and one of the two parts remains as step portion 50 in a lateral surface of solder-provided submount 10A.

Here, a desirable form of first solder layer 30X in solder-provided submount assembly 10X is described with reference to FIG. 22.

First, as shown in (d) in FIG. 22, at a position immediately below a central portion of groove 50X in the longer-side direction, the length (D2, D5 in FIG. 22) of a region including first solder layer 30X in the longer-side direction of groove 50X may be at most 200 μm. In other words, at the position immediately below groove 50x, a distance between two adjacent opening portions 33X in first solder layer 30X may be at most 200 μm.

In the case where a distance between two adjacent opening portions 33X becomes excessive at a position immediately below a portion (one of grooves 50X in the lattice pattern) at which solder-provided submount assembly 10X is to be divided, first solder layer 30X increases in size, which makes it difficult to separate first solder layer 30X when the expanded sheet is expanded. By setting the distance between two adjacent opening portions 33X to at most 200 μm, however, it is possible to divide first solder layer 30X readily along the plurality of opening portions 33X.

It should be noted that in first solder layer 30X, distance D2 between two adjacent opening portions 33X on the side closer to the longer side may be greater than distance D5 between two adjacent opening portions 33X on the side closer to the shorter side (D2>D5). This makes it possible to effectively prevent submount 10 likely to tilt in the shorter-side direction from tilting. In addition, in consideration of a usage pattern of a submount after division, D2 and D5 may be at least 20 μm and at most 200 μm.

Moreover, as shown in (d) in FIG. 22, at the position immediately below the central portion of groove 50X in the longer-side direction, the length (D1, D4 in FIG. 22) of a region not including first solder layer 30X in the longer-side direction of groove 50X may be at most 20 μm. To put it another way, at the position immediately below groove 50X, the length of opening portion 33X along groove 50X may be at most 20 μm.

Since this causes the region that includes first solder layer 30X and serves as a division constraint when solder-provided submount assembly 10X is divided to decrease in size, it is possible to divide first solder layer 30X readily. In addition, in consideration of a usage pattern of a submount after division, D1 and D4 may be at least 20 μm and at most 200 μm.

Furthermore, as shown in (d) in FIG. 22, in the longer-side direction of groove 50X, a distance (D6 in FIG. 22) between the center line of groove 50X and an edge of the region not including first solder layer 30X may be at least 20 μm. In other words, at a position immediately below groove 50X, a distance between the center line of groove 50X and an edge of opening portion 33X may be at least 20 μm.

When solder-provided submount assembly 10X is divided by a physical stress, a division surface is not necessarily perpendicular to a division main surface and may be displaced. At this time, when a distance from a remaining thickness of groove 50X to the surface of substrate 11X is approximately 100 μm, the displacement of the division surface is less than 20 μm from the center line of groove 50X. In view of the above, by setting distance D6 between the center line of groove 50X and the edge of opening portion 33X to at least 20 μm, opening portion 33X is caused to extend to a portion at a distance of at least 20 μm from the center line of groove 50X. Since this causes the edge of the division surface to overlap opening portion 33X, it is possible to prevent first solder layer 30X from not being separated when the expanded sheet is expanded (i.e., the occurrence of twins). Excessive distance D6 causes space for mounting the semiconductor laser on the top surface to decrease. Accordingly, for example, distance D6 may be at most 200 μm. In addition, in consideration of a usage pattern of a submount after division, D6 may be at least 40 μm and at most 200 μm that are twice as much as d3 and d6.

It should be noted that although the plurality of opening portions 33X are not provided in the outer peripheral edge portion of first solder layer 30X in solder-provided submount assembly 10X shown in FIG. 22, the present disclosure is not limited to this example. For example, as in solder-provided submount assembly 10Y according to Variation 1 shown in FIG. 25, a plurality of opening portions 33X may be intermittently provided at positions immediately below grooves 50X in a lattice pattern, and at the same time may be intermittently provided along an outer peripheral edge portion of first solder layer 30X. In this case, each of the plurality of opening portions 33X in the outer peripheral edge portion of first solder layer 30X is provided to notch the outer peripheral edge portion of first solder layer 30X. FIG. 25 is a view of a configuration of solder-provided submount assembly 10Y according to Variation 1. In FIG. 25, (a) is a top view, (b) and (c) are side views, and (d) is a rear view.

It is also possible to manufacture solder-provided submount assembly 10Y shown in FIG. 25 in the same manner as solder-provided submount assembly 10X shown in FIG. 22. For example, it is possible to provide grooves 50X of substrate 11X by radiating laser light etc.

In addition, it is possible to divide, into parts, solder-provided submount assembly 10Y shown in FIG. 25 along grooves 50X in the lattice pattern by applying a physical stress to perform breakup, and to subsequently separate solder-provided submount assembly 10Y into individual solder-provided submounts 10A by performing expanding using an expanded sheet.

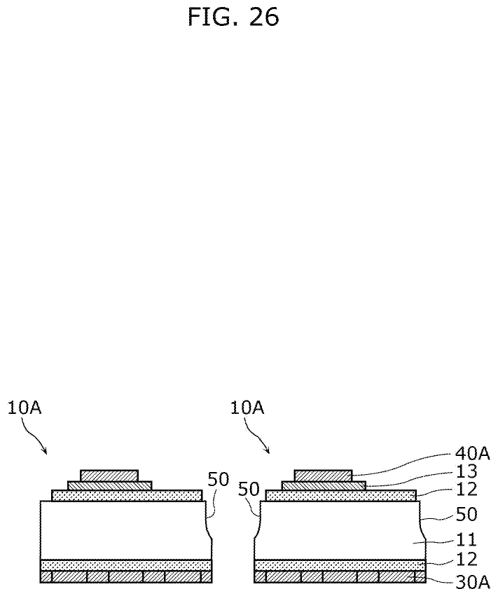

At this time, when solder-provided submount assembly 10Y shown in FIG. 25 is used, as shown in FIG. 26, not only solder-provided submount 10A that includes both end portions in which step portions 50 are provided in a width direction is obtained, but also solder-provided submount 10A that includes both end portions in only one of which step portion 50 is provided in the width direction is obtained. In other words, bilaterally asymmetrical solder-provided submount 10A is also manufactured.

As stated above, when a plurality of solder-provided submounts 10A are manufactured by dividing solder-provided submount assembly 10X shown in FIG. 22, a division loss occurs since grooves 50X to be division lines are provided not in end portions of substrate 11X but in portions inward of the end portions, and the plurality of solder-provided submounts 10A manufactured are bilaterally asymmetrical.

In contrast, when a plurality of solder-provided submounts 10A are manufactured by dividing solder-provided submount assembly 10Y shown in FIG. 25, a division loss does not occur since grooves 50X to be division lines are not provided in end portions of substrate 11X, and bilaterally asymmetrical solder-provided submounts 10A are included in the plurality of solder-provided submounts 10A manufactured.

Moreover, although, in solder-provided submount assembly 10X shown in FIG. 22, grooves 50X are provided to manufacture the plurality of solder-provided submounts 10A, the present disclosure is not limited to this example. In other words, a solder-provided submount assembly may be divided into parts without providing grooves 50X on substrate 11X. For example, when substrate 11X is a SiC substrate or an AlN substrate, it is possible to divide a solder-provided submount assembly into parts without providing grooves 50X on substrate 11X.

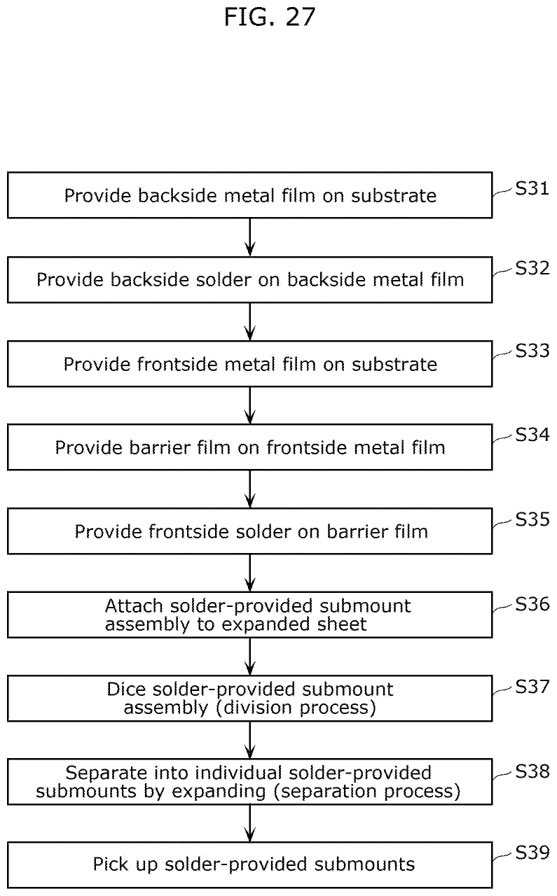

In this case, a method shown in FIG. 27 makes it possible to divide a solder-provided submount assembly into parts. FIG. 27 is a flow chart illustrating a variation of the method of manufacturing the solder-provided submount.

First, a backside metal film is provided on substrate 11X (step S31). Specifically, as with step S22 shown in FIG. 23, first metal film 12X is provided as the backside metal film on a lower surface of substrate 11X.

Next, backside solder is provided on the backside metal film (step S32). Specifically, as with step S23 shown in FIG. 23, first solder layer 30X is provided as the backside solder on the lower surface of first metal film 12X that is the backside metal film. At this time, first solder layer 30X that includes a plurality of opening portions 33X in a lattice pattern is provided.

After that, a frontside metal film is provided on substrate 11X (step S33). Specifically, as with step S24 shown in FIG. 23, second metal film 13X is provided as the frontside metal film on the lower surface of substrate 11X.

Next, barrier film 14X is provided on the frontside metal film (step S34). Specifically, as with step S25 shown in FIG. 23, barrier film 14X is provided on an upper surface of second metal film 13X that is the frontside metal film.

Then, frontside solder is provided on barrier film 14X (step S35). Specifically, as with step S26 shown in FIG. 23, second solder layer 40X is provided as the frontside solder on an upper surface of barrier film 14X.

Accordingly, it is possible to manufacture a solder-provided submount assembly on which grooves 50X are not provided.

After that, the solder-provided submount assembly is attached to an expanded sheet (step S36). Specifically, as with step S27 shown in FIG. 23, the solder-provided submount assembly is disposed on the expanded sheet.

Next, the solder-provided submount assembly is diced (step S37). Specifically, the solder-provided submount assembly is diced from a back surface of the expanded sheet. At this time, the solder-provided submount assembly is diced along a plurality of opening portions 33X provided in a frame pattern. Accordingly, the solder-provided submount assembly is divided into a plurality of solder-provided submounts.

Then, separation into individual solder-provided submounts is performed by expanding the expanded sheet (step S38). Specifically, as with step S39 shown in FIG. 23, the expanded sheet is expanded.

Finally, the solder-provided submounts are picked up (step S39). Specifically, as with step S30 shown in FIG. 23, the solder-provided submounts are picked up.

Accordingly, it is possible to obtain the plurality of solder-provided submounts. Since grooves 50X are not provided in solder-provided submount the assembly, step portions corresponding to grooves 50X are not provided in the solder-provided submounts thus obtained.

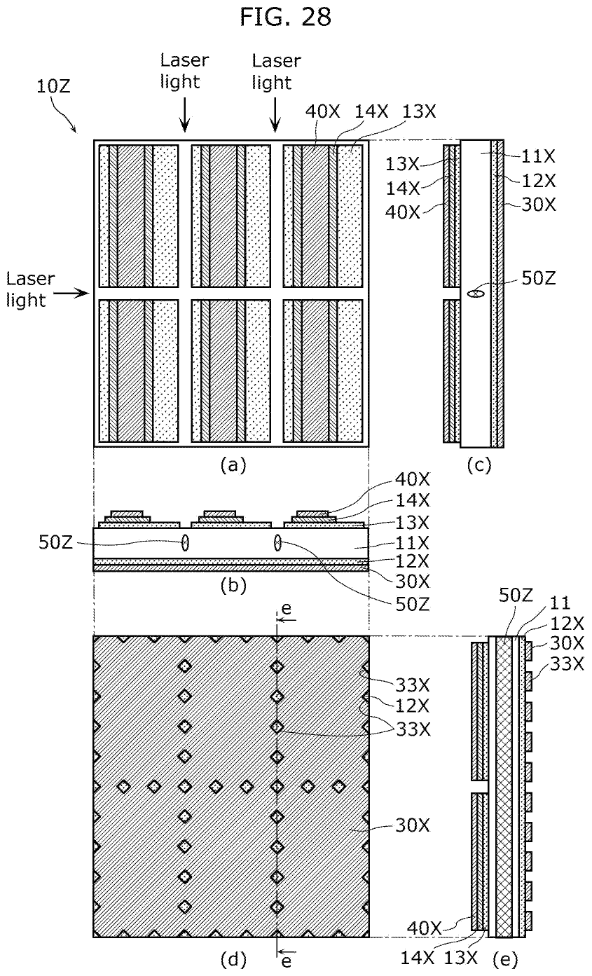

Furthermore, as an other variation, a plurality of solder-provided submounts 10A may be manufactured using solder-provided submount assembly 10Z shown in FIG. 28. FIG. 28 is a view of a configuration of solder-provided submount assembly 10Z according to Variation 2. In FIG. 28, (a) is a top view, (b) and (c) are side views, (d) is a rear view, and (e) is a cross-sectional view taken along line e-e in (d).

In solder-provided submount assembly 10Z shown in FIG. 28, grooves 50X are not provided on substrate 11X, and instead of grooves 50X, alteration portions 50Z in a lattice pattern are provided inside substrate 11X.

In this case, for example, a diamond substrate is used as substrate 11X, and it is possible to provide alteration portions 50Z in the lattice pattern inside substrate 11X by radiating laser light to substrate 11X in grid-like fashion. When the laser light is radiated to substrate 11X, the diamond is melted by the laser light, and portions inside substrate 11X are altered into alteration portions 50Z containing conductive carbon.

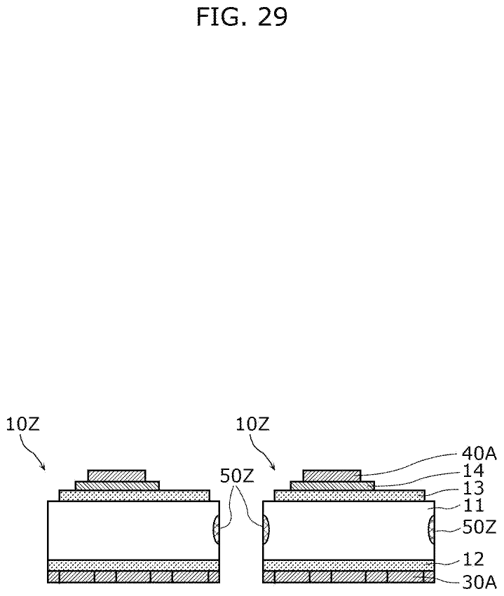

It is possible to separate solder-provided submount assembly 10Z thus obtained into parts along alteration portions 50Z in the lattice pattern by applying a physical stress to perform breakup, and to subsequently separate solder-provided submount assembly 10Z into individual solder-provided submounts 10A by performing expanding using an expanded sheet. At this time, as shown in FIG. 29, solder-provided submount 10A in which alteration portions 50Z are located on the lateral surfaces of insulative component 11 (substrate 11X) is manufactured.

It should be noted that, as an other variation, solder-provided submount assembly 10P shown in FIG. 30 may be used. FIG. 30 is a view of a configuration of solder-provided submount assembly 10P according to Variation 3. In FIG. 30, (a) is a rear view and (b) is a cross-sectional view taken along line b-b in (a).

In solder-provided submount assembly 10P shown in FIG. 30, opening portion 33P through which first metal film 12X is exposed is further provided in a central portion (i.e., a portion that does not contribute to division) of each of frames of a plurality of opening portions 33X in a lattice pattern located immediately below grooves 50X in the lattice pattern. In other words, after the division, a central portion of insulative component 11 to be solder-provided submount 10A includes a region not including first solder layer 30X.

Since it is possible to decrease area of contact between an expanded sheet and solder-provided submount assembly 10P by providing opening portions 33P separately other than immediately below grooves 50X in the lattice shape as above, it is possible to pick up solder-provided submounts 10A readily. To put it another way, it is possible to readily push up solder-provided submounts 10A on the expanded sheet using push-up pins, and to improve pick-up performance. Additionally, since opening portions 33P are provided in portions that do not intersect with grooves 50X to be division lines, opening portions 33P do not have an effect on the division of solder-provided submount assembly 10P. It should be noted that since it is possible to further decrease the area of contact between the expanded sheet and solder-provided submount assembly 10P by providing a plurality of opening portions 33P, it is possible to further improve the pick-up performance. In addition, since exposed portions exposed by openings are first metal film 12X having a high solder wettability, it is possible to promote expansion of solder at the time of mounting.

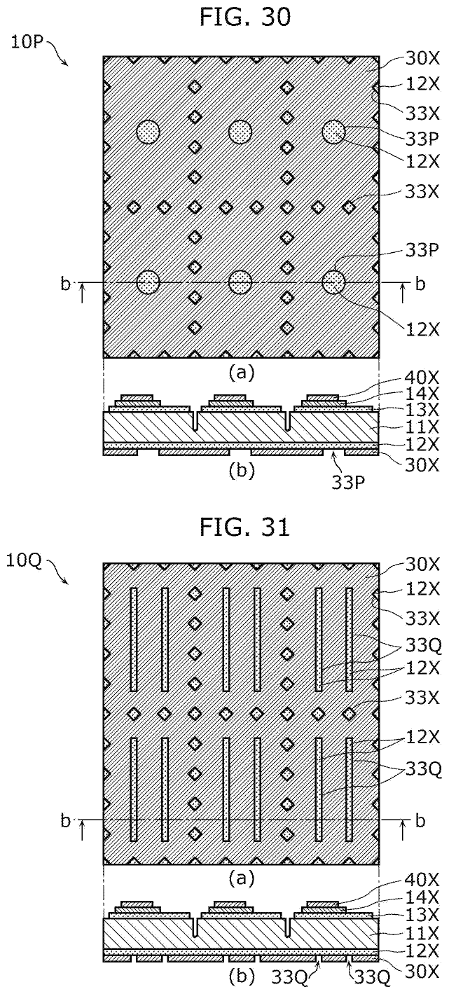

Moreover, solder-provided submount assembly 10Q shown in FIG. 31 may be used. FIG. 31 is a view of a configuration of solder-provided submount assembly 10Q according to Variation 4. In FIG. 31, (a) is a rear view and (b) is a cross-sectional view taken along line b-b in (a).

In solder-provided submount assembly 10Q shown in FIG. 31, opening portion 33Q or opening portions 33Q that are in a belt shape and parallel to a longer-side direction of submount 10 are provided in each of frames in a lattice pattern (i.e., a portion that does not contribute to division) including a plurality of opening portions 33X through which first metal film 12X is exposed.

This configuration makes it possible to improve separation performance of expanding when separation into a plurality of solder-provided submounts 10A is performed by expanding an expanded sheet to which solder-provided submount assembly 10Q is attached. In addition, since it is possible to decrease area of contact between the expanded sheet and solder-provided submount assembly 10Q, it is also possible to pick up solder-provided submounts 10A readily.

### [Method of Testing Semiconductor Laser Device]

Hereinafter, a method of testing semiconductor laser device 1 shown in FIG. 1 and FIG. 2 is described with reference to FIG. 1 to FIG. 4.

As described above, it is possible to join submount 10 and pedestal 3 with solder 30 by heating solder-provided submount 10A and semiconductor laser 20 disposed on pedestal 3 of a stem. At this time, it is possible to determine a tilt (parallelity) of submount 10 by measuring a state of a plurality of protruding portions 31a of solder 30.

Specifically, a visual test with image recognition by use of a camera makes it possible to determine the tilt of submount 10 by measuring the number, positions, size, and/or shape of the plurality of protruding portions 31a of solder 30 and evaluating uniformity. For example, when a pair of longer sides or a pair of shorter sides of submount 10 has the same number of protruding portions 31a, it is possible to determine that a state of solder 30 in a horizontal direction or a vertical direction is uniform, and to determine that submount 10 does not tilt. It should be noted that it is possible to select semiconductor laser device 1 based on the degree of tilt of submount 10.

It should be noted that it is possible to realize the method of testing semiconductor laser device 1 as a test step in the above-described method of manufacturing semiconductor laser device 1. In addition, it is also possible to realize the method of testing semiconductor laser device 1 as a method of evaluating semiconductor laser device 1.

### Variations

Although the semiconductor laser device etc. according to the present disclosure has been described based on the embodiment above, the present disclosure is not limited to the aforementioned embodiment.

For example, although semiconductor laser 20, submount 10, and pedestal 3 are simultaneously joined in the aforementioned embodiment, the present disclosure is not limited to this example. For example, semiconductor laser 20 may be mounted on submount 10 in advance, submount 10 on which semiconductor laser 20 has been mounted may be disposed on pedestal 3, and submount 10 and pedestal 3 may be joined with solder 30 by melting first solder layer 30a with heat.

Moreover, although first metal film 12 and second metal film 13 each have the three-layer structure in which the Ti layer, the Pt layer, and the Au layer are sequentially stacked in the aforementioned embodiment, the present disclosure is not limited to this example. For example, first metal film 12 and second metal film 13 may each have a four-layer structure in which a Cu layer (approximately 75 μm), a Ti layer, a Pt layer, and an Au layer are sequentially stacked in stated order from a side closer to insulative component 11 such as AlN.

It should be noted that, as other examples, forms obtained by various modifications to the aforementioned embodiment that can be conceived by a person skilled in the art or forms achieved by arbitrarily combining the constituent elements and functions in the embodiment are included in the scope of the present disclosure as long as they do not depart from the essence of the present disclosure.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The semiconductor laser device according to the present disclosure is useful as an image display device such as a projector, a vehicle part such as an in-vehicle headlamp, a luminaire such as a spotlight, or a light source for products in various industrial fields such as laser processing equipment.

1. A semiconductor laser device comprising:
a pedestal;
a submount that is joined to the pedestal via solder; and
a semiconductor laser that is mounted on the submount,
wherein when a view of the submount from a side on which the semiconductor laser is mounted is defined as a top view, in the top view:
the solder includes a plurality of protruding portions; and
the plurality of protruding portions are provided on the pedestal outside the submount, protrude in directions away from an inside of the submount, and are located at regular intervals on at least a portion of a periphery of the submount.

2. The semiconductor laser device according to claim 1,
wherein all of the plurality of protruding portions are provided on the pedestal outside the submount, protrude in the directions away from the inside of the submount, and are located at regular intervals.

3. The semiconductor laser device according to claim 1,
wherein in the top view, borders between the submount and the plurality of protruding portions are located at regular intervals.

4. The semiconductor laser device according to claim 1,
wherein the solder includes an outer peripheral portion that protrudes from an outer edge of the submount, and
the plurality of protruding portions protrude from the outer peripheral portion in the directions away from the inside of the submount.

5. The semiconductor laser device according to claim 1,
wherein in the top view, at least one of the plurality of protruding portions is located on an optical axis of the semiconductor laser.

6. The semiconductor laser device according to claim 1,
wherein in the top view, a length of a border between the submount and one of the plurality of protruding portions is at least 20 μm and at most 200 μm.

7. The semiconductor laser device according to claim 1,
wherein in the top view, a portion of the solder that does not protrude from an outer edge of the submount and in which an outer edge of the solder coincides with the outer edge of the submount has a length of at most 200 μm.

8. The semiconductor laser device according to claim 1,
wherein a top view shape of the submount is a rectangle, and
when a total number of at least two protruding portions on one side of the rectangle is denoted by n, and an amount of protrusion from an outer edge of the submount in each of the at least two protruding portions is denoted by Di, where i is an integer and satisfies 1≤i≤n, the at least two protruding portions being included in the plurality of protruding portions,
in the one side of the rectangle, a standard deviation of Di is at most 50% of an average value of Di.

9. The semiconductor laser device according to claim 1,
wherein a top view shape of the submount is a rectangle, and
when a total number of a plurality of protruding portions on one side of the rectangle is denoted by n, and distances between the plurality of protruding portions are each denoted by Pi, where i is an integer and satisfies 1≤i≤n−1,
a standard deviation of Pi is at most 20% of an average value of Pi,
the distances between the plurality of protruding portions on the one side of the rectangle include a group that includes a first distance having a standard deviation that falls within 10%, and a group that includes a second distance having a standard deviation that falls within 10%, and
the second distance is at most 1.5 times as much as the first distance.

10. The semiconductor laser device according to claim 9,
wherein the distances between the plurality of protruding portions on the one side of the rectangle further include a group that includes a third distance that is different from the first distance and the second distance and has a standard deviation that falls within 10%, and
the third distance is at most twice as much as the first distance.

11. A submount comprising:
an insulative component;
a metal film; and
a solder layer,
wherein the metal film is disposed on a surface of the insulative component on one side,
the solder layer is disposed on a surface of the metal film on the one side, and
an outer edge of the surface of the metal film on the one side includes a portion in which a first region in which the solder layer is located and a second region in which the solder layer is not located are alternately located.

12. The submount according to claim 11,
wherein the surface of the insulative component on the one side has a width greater than a width of a surface of the insulative component on an other side opposite to the one side.

13. The submount according to claim 11,
wherein a lateral surface of the insulative component includes an alteration portion.

14. The submount according to claim 11,
wherein in a plan view of the solder layer, each of first regions in the outer edge of the surface of the metal film on the one side has a length of at least 20 μm and at most 200 μm, the first regions each being the first region.

15. The submount according to claim 11,
wherein in a plan view of the solder layer, each of second regions in the outer edge of the surface of the metal film on the one side has a length of at least 20 μm and at most 200 μm, the second regions each being the second region.

16. The submount according to claim 11,
wherein an opening portion is provided in an outer peripheral end portion of the solder layer,
in a plan view of the solder layer, the opening portion is a notch that recedes inwardly from an outer peripheral end portion of the insulative component,
the outer edge of the surface of the metal film on the one side in the opening portion is the second region, and
in a plan view of the solder layer, a length between one end portion and an other end portion of the opening portion in the outer peripheral end portion of the insulative component is at least 20 μm and at most 100 μm, the other end portion being opposite to the one end portion.

17. The submount according to claim 11,
wherein in one side of an outer edge of the insulative component, the first region in a central portion of the one side has a length less than a length of the first region in a portion closest to an end portion of the one side.

18. A submount assembly comprising:
a substrate;
a metal film; and
a solder layer,
wherein the metal film is disposed on a surface of the substrate on one side,
the solder layer is disposed on a surface of the metal film on the one side,
grooves in a lattice pattern are provided on a surface of the submount assembly on an other side or alteration portions in a lattice pattern are provided inside the substrate, the other side being opposite to the one side, and
a portion in which regions not including the solder layer are located at regular intervals is located immediately below one of the grooves or one of the alteration portions.

19. The submount assembly according to claim 18,
wherein immediately below a central portion of the one of the grooves or the one of the alteration portions in a longer-side direction, a region in which the solder layer is located in the longer-side direction has a length of at most 200 μm.

20. A method of testing a semiconductor laser device,
wherein the semiconductor laser device includes:
a pedestal;
a submount that is joined to the pedestal via solder; and
a semiconductor laser that is mounted on the submount,
when a view of the submount from a side on which the semiconductor laser is mounted is defined as a top view, in the top view:
the solder includes a protruding region that protrudes from an outer edge of the submount,
the protruding region includes a plurality of protruding portions that protrude outwardly, and
the method comprises determining a tilt of the submount by measuring a state of the plurality of protruding portions.
